(19) United States
(12) Patent Application Publication
(10) Pub. No.: US 2012/0312351 A1
(43) Pub. Date: Dec. 13, 2012

(54) Efficient solar energy concentrator with improved thermal management

(75) Inventor: Richard Morris Knox, Austin, TX (US)

(73) Assignee: RayDyne Energy, Inc., Austin, TX (US)

(21) Appl. No.: 13/507,142

(22) Filed: Jun. 7, 2012

Related U.S. Application Data
(63) Continuation-in-part of application No. 13/200,225, filed on Sep. 21, 2011.
Application No. 13/200,225 is a continuation-in-part of application No. 12/572,913, filed on Oct. 2, 2009, now abandoned.
(60) Provisional application No. 61/628,509, filed on Nov. 1, 2011.
(60) Provisional application No. 61/520,289, filed on Jun. 7, 2011.
(60) Provisional application No. 61/403,853, filed on Sep. 22, 2010.
(60) Provisional application No. 61/102,306, filed on Oct. 2, 2008.

(51) Int. Cl. H01L 31/052

(52) U.S. Cl. 136/246

(57) ABSTRACT

A solar concentrator comprises a reflective curved mirror assembly, a support riser placed to support and position photovoltaic cells attached to a printed circuit board that is in turn attached to a heat sink at the focal point of the mirrors of the reflective curved mirror assembly. A central support riser may grasp the assembly of photovoltaic cells attached to a printed circuit board while other support risers may allow the assembly of photovoltaic cells to move slightly to accommodate differences in the coefficient of thermal expansion between the mirror assembly and the printed circuit board and the heat sink. The solar concentrator may include a prism assembly placed to separate solar radiation angularly by wavelength to facilitate use of single junction photovoltaic cells for increased efficiency. The heat sink may form the major structural element of the solar concentrator.

### CROSS-REFERENCE TO RELATED APPLICATIONS

This application is a Continuation-in-Part of pending U.S. patent application Ser. No. 13/200,225, published as 2012/0024374, filed Sep. 2, 2011, the entire contents whereof are incorporated into this application by reference, and this application is a Continuation-in-Part of pending U.S. patent application, Ser. No. 12/572,913, published as 2012/0108124, filed Oct. 2, 2009, the entire contents whereof are incorporated into this application by reference, and this application claims priority to U.S. Provisional Application Ser. No. 61/520,289, filed Jun. 7, 2011, the entire contents whereof are incorporated into this application by reference, and this application claims priority to U.S. Provisional Application 61/628,509, filed Nov. 1, 2011, the entire contents whereof are incorporated into this application by reference.

### FIELD OF THE INVENTION

This invention relates to a solar concentrator utilizing photovoltaic cells to convert concentrated solar radiation into electrical energy. More specifically, the present invention relates to a solar concentrator with improved thermal management structures to cool the photovoltaic cells as is known to be necessary. In one embodiment the solar concentrators comprises a prismatic structure to illuminate a plurality of single junction photovoltaic cells to convert solar radiation into electrical energy.

### BACKGROUND OF THE INVENTION

Concentrators for solar energy have been in use for many years. These devices are used to focus the sun's energy into a small area to raise the power level being concentrated on a photovoltaic converter to generate electrical power directly, or on a fluid line to heat water to make steam to drive a turbine to generate electrical power.

One difficulty with these concentrators has been that they are generally large and bulky and are not suitable for residential applications or other locations where the aesthetics of the installation are of importance. Additionally they are very susceptible to environmental damage due to wind and other elements.

In a common implementation a refractive or reflective lens is used to focus the energy on a small photovoltaic device. An example of a refractive device 100 is presented in FIG. 1 that shows conventional Fresnel lens 105 concentrating solar illumination depicted as rays a, b, and c on photovoltaic cell 110. The concept and design are very simple and the placement of photovoltaic cell 110 on the side opposite the sun results in a system that is easy to manage thermally. It suffers from a number of disadvantages. Fresnel lenses are prone to diffraction loss and geometric light-trapping loss and require a long focal length and can be on the order of 12 to 15 inches. More importantly the least expensive way to form a Fresnel lens is with a mold in plastic. Plastic deteriorates in direct sunlight because of the ultra-violet components. Peak reported efficiency for this type system is 82%.

An example of a reflective solar concentrator device 120 is presented in FIG. 2. The optical principle is that of a Cassegrain telescope first made known in the seventeenth century, with an energy conversion device replacing the eyepiece. Specifically, solar illumination depicted as rays a, b, c, d, e, and f enters Cassegrain system 120 and is reflected by main reflector 125 to secondary reflector 135. Secondary reflector 135 reflects the illumination through aperture 130 to a photovoltaic cell (not shown). It suffers from the deficiency that secondary-reflector 135 blocks a substantial portion of the aperture of main reflector 125 and thus reduces the effective ability of the device to concentrate light. It is shorter than the Fresnel system of FIG. 1 and the placement of the photovoltaic cell on the side opposite the sun results in a system that is again easier to manage thermally. Disadvantages include multiple reflection losses due to the extra mirror, a more complex alignment process and the aforementioned aperture blocking. Peak reported efficiency for this type system is 75%.

FIG. 3 depicts a simplified drawing of single reflection solar concentrator 140. Solar radiation, depicted as rays a and b, are reflected by curved mirror 145 to photovoltaic cell 150. This type system has the highest reported efficiency at 89% and the shortest focal length, meaning the thinnest panel. Difficulties include mounting the photovoltaic cell, wiring the photovoltaic cell in and dissipating heat since the photovoltaic cell is on the solar side of the device. The curvature of the mirror is often parabolic although elliptical or other surfaces are possible.

An additional problem of concentrator assemblies similar to system 140 is the type of photovoltaic cell used. The photovoltaic cell is a type commonly referred to as “triple junction” photovoltaic cells. The design is well known to those of ordinary skill in the art.

FIG. 4A illustrates one of the difficulties with the triple junction photovoltaic material of the system of FIG. 3. FIG. 4A depicts efficiency curves of a triple junction cell in tandem configuration and optimized for AM 1.5 spectrum over the course of a day. By inspection it is clear that the photovoltaic cell of the example is most efficient when the sun is at 48.2 degrees with respect to the horizon at AM 1.5, but suffers significantly as the solar spectrum varies with AM (air mass) throughout the day. The lower curve demonstrates the efficiency of a triple junction cell with all cells wired together in series as is normally the case. The upper curve demonstrates the combined efficiency of each layer of a triple junction cell when the individual cells are not connected in series and allowed to generate independently.. This illustrates the important point that triple junction material enables simplified optical structures but at the price of significant lost efficiency because of the need to wire the individual components in series effectively forcing the entire cell to operate at the current level of the least producing layer of the three. A single junction photovoltaic system comprising a plurality of photovoltaic devices operating at different band gaps for different solar spectra must necessarily have a more complex optical structure.

FIG. 4B illustrates a triple junction photovoltaic (PV) cell. The PV cell comprises three stacked PV cells with different band gaps. Top cell 146 comprises a Gallium-Indium-Phosphide layer with a bandgap of 1.85 eV to capture photons in the ultraviolet and visible part of the solar spectra. Middle cell 147 comprises a Gallium Arsenide layer with a bandgap of 1.42 eV to capture photons in the near infrared spectra. Bottom cell 148 comprises a Germanium layer with a bandgap of 0.67 eV that captures all the lower photon energies in the infrared that are above 0.67 eV. Tunnel junction 149 interconnects top cell 146 to middle cell 147 and tunnel junction and GaAs layer 151 interconnect middle cell 147 to bottom cell 148. Positive and negative electrical contacts 152 and 153 are affixed respectively to the bottom of the bottom cell and the top of the top cell. Important considerations in the selection of material for the layers include a need to match the crystalline structure of the layers (lattice matching). Another important consideration is that the three cells must be current matched. These considerations are well known in the art. While additional layers of other materials to further sub-divide the spectrum and further increase power harvest are possible, they correspondingly increase the cells' sensitivity to solar spectral shifts due to AM (air mass for solar energy) changes.

FIG. 4C presents a graph of external quantum efficiency versus wavelength for a triple junction cell of FIG. 4B.

### BRIEF DESCRIPTION OF THE DRAWINGS

FIG. 1 depicts a prior art Fresnel lens refractive solar concentrator

FIG. 2 depicts a prior art Cassegrain reflective solar concentrator.

FIG. 3 depicts a single reflection solar concentrator..

FIG. 4A presents a chart of the efficiency of a triple junction photovoltaic device as a function of elevation angle.

FIG. 4B depicts the layers of materials forming a triple junction photovoltaic cell.

FIG. 4C presents a graph of external quantum efficiency as a function of wavelength for a triple junction photovoltaic cell.

FIG. 5A depicts a perspective view of a solar concentrator assembly after the present invention.

FIG. 5B depicts a second perspective view of a solar concentrator assembly after the present invention

FIG. 5C depicts a solar concentrator assembly after the present invention from the perspective of FIG. 5B with the heat sink removed.

FIG. 6A is a detailed view of a mirror segment, support structure, photovoltaic assembly and heat sink after the present invention.

FIG. 6B is a section view of a mirror segment, photovoltaic assembly section and heat sink section after the present invention.

FIG. 7A depicts a solar concentrator system comprising a plurality of solar concentrator assemblies, a cover glass and a frame.

FIG. 7B presents an expanded view of a solar concentrator system comprising a plurality of solar concentrator assemblies, a cover glass, and a frame.

FIG. 8A depicts a section of a photovoltaic assembly comprising a set of photovoltaic cells mounted on a printed circuit board.

FIG. 8B presents an electrical schematic of a plurality of photovoltaic cells connected in series.

FIG. 8C depicts an electrical schematic of a plurality of photovoltaic cells connected in parallel.

FIG. 9 depicts a top view of a photovoltaic cell comprising the upper surface of said photovoltaic cells, a plurality of fine grid wires spanning said surface and a plurality of electrical contacts for said fine grid wires.

FIG. 10A and FIG. 10B depict the upper and lower surface of a printed circuit configured to connect a plurality of photovoltaic cells in series.

FIG. 11A depicts an end view of a heat sink and photovoltaic cell wherein the heat sink acts as one conductor for a photovoltaic assembly wired in parallel.

FIG. 11B depicts an end view of a heat sink, insulating layer and copper trace electrically isolated from said heat sink,

FIG. 11C depicts a view of a heat sink with photovoltaic cell, insulating layer and copper trace affixed thereto.

FIG. 11D depicts an alternative means of arranging a plurality of printed circuit boards with photovoltaic cells attached thereto on a heat sink to form a photovoltaic assembly wired in series.

FIG. 12 depicts a means of attached a fin shaped heat sink to a photovoltaic assembly.

FIG. 13A depicts a solar concentrator assembly wherein a heat sink assembly forms a base supporting a mirror assembly and forms a set of risers supporting a photovoltaic assembly.

FIG. 13B depicts an end view of a heat sink with a mirror assembly in place and a plane view of a set of mirror half segments.

FIG. 13C depicts a heat sink arrangement for a photovoltaic assembly wherein photovoltaic cells are wired in series.

FIG. 13D depicts the mating of a photovoltaic assembly to a heat sink wherein said heat sink proves risers with clear apertures for photovoltaic cells.

FIG. 14A depicts an end view of an extruded heat sink comprising a riser, a base and a plurality of cooling fins.

FIG. 14B depicts a side view of an extruded heat sink wherein a clear aperture has been punched into a set of risers such that photovoltaic cells of a photovoltaic assembly are centered over the clear apertures.

FIG. 14C depicts an end view of an alternative extruded heat sink comprising a riser, a base and a plurality of cooling fins.

FIG. 14D depicts a side view of an extruded heat since wherein a clear aperture punched into said heat sink riser provides alignment features to facilitate installing a mirror assembly.

FIG. 15A depicts an arrangement of a plurality of single junction photovoltaic cells arrayed so as to form a single junction photovoltaic assembly.

FIG. 15B depicts optical means for separating solar radiation by spectrum and deliveries said separated spectra to single junction photovoltaic cells.

FIG. 15C presents a schematic of a method of wiring a single junction photovoltaic assembly comprising a plurality of differing single junction materials.

FIG. 16A depicts a prism assembly affixed to a substrate.

FIG. 16B depicts the path solar radiation takes through a prism and the angular separation of solar radiation by wavelength upon exiting said prism.

FIG. 17A depicts a solar concentrator comprising a prism assembly affixed to the underside of a cover glass.

FIG. 17B present definitions of the angles of a prism and of solar radiation passing through said prism and defines the names of the lengths of the surface of said prism and of solar radiation passing through said prism.

FIG. 17C presents a table defining the angles of a prism and containing calculated data for the angles solar radiation takes through said prism and data described offset distance between different spectra.

FIG. 17D presents a table containing a normalized specification of key lengths of a prism and calculated distance for solar radiation passing through said prism.

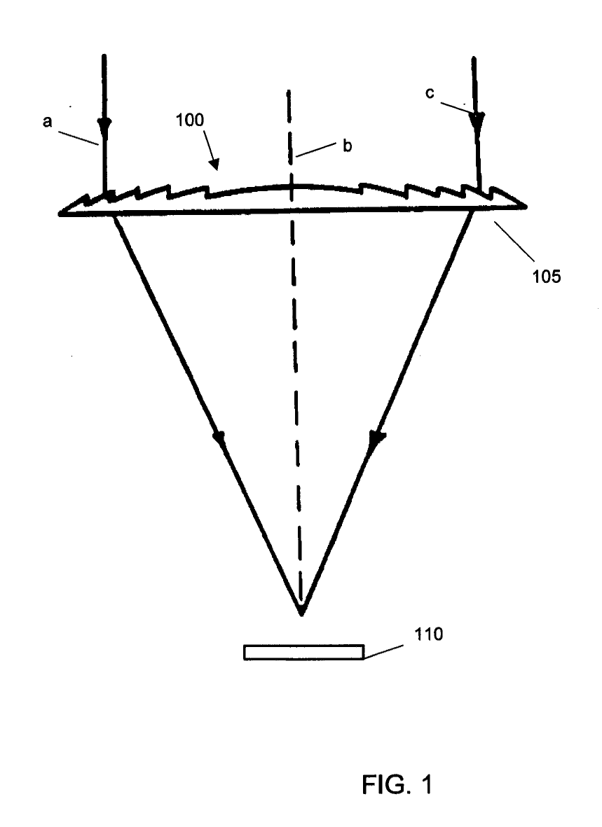

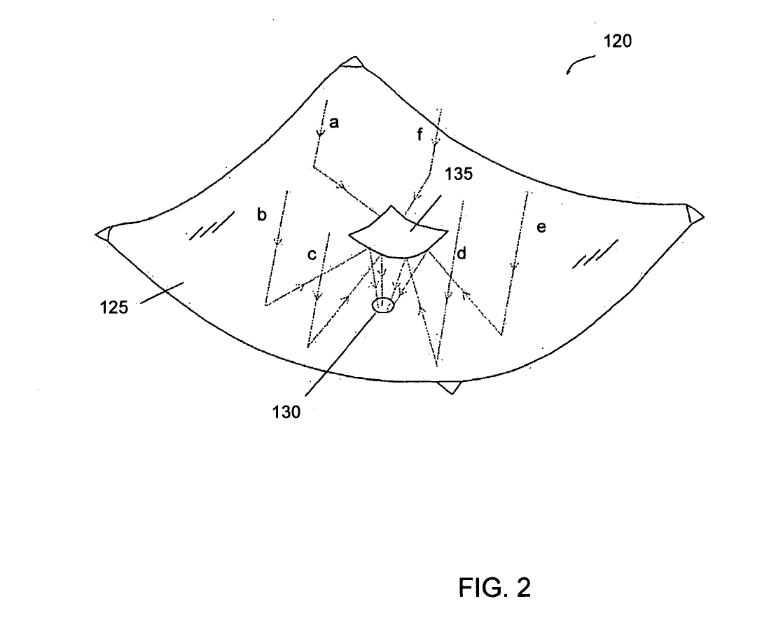

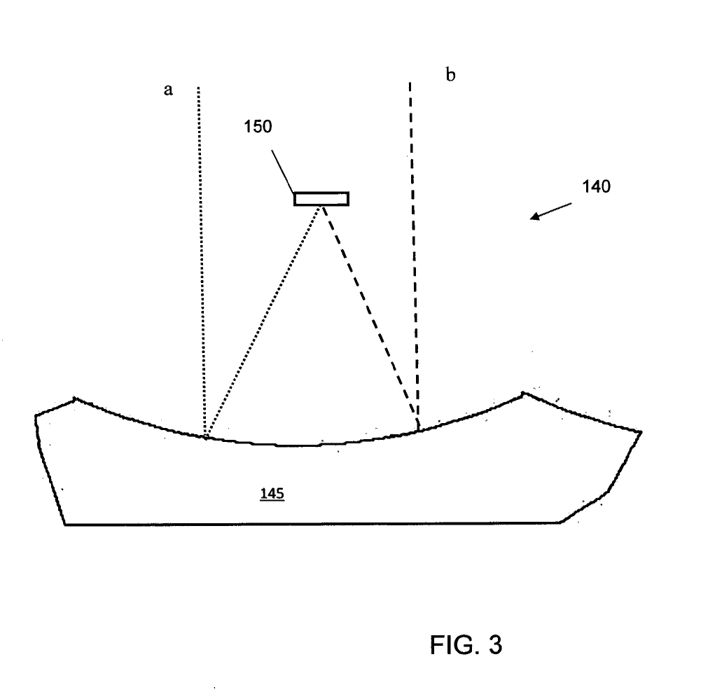

### DESCRIPTION OF THE INVENTION

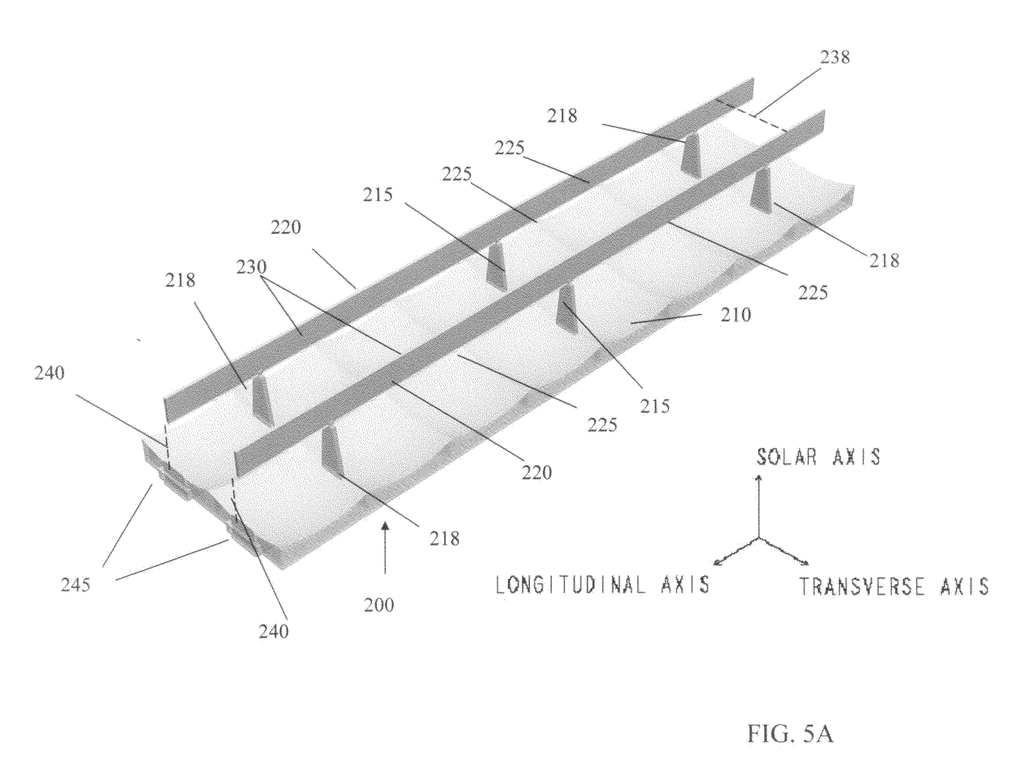

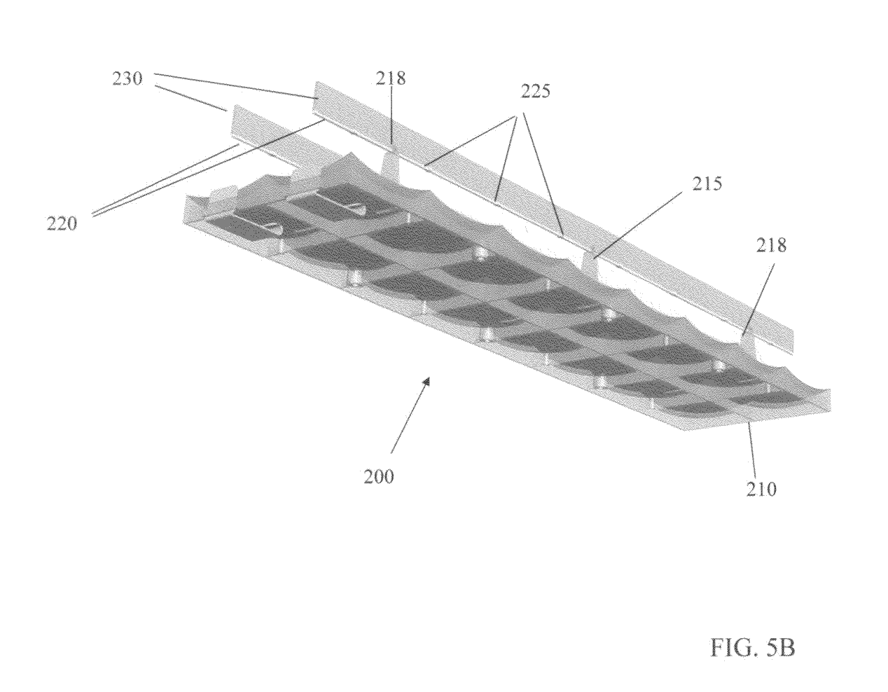

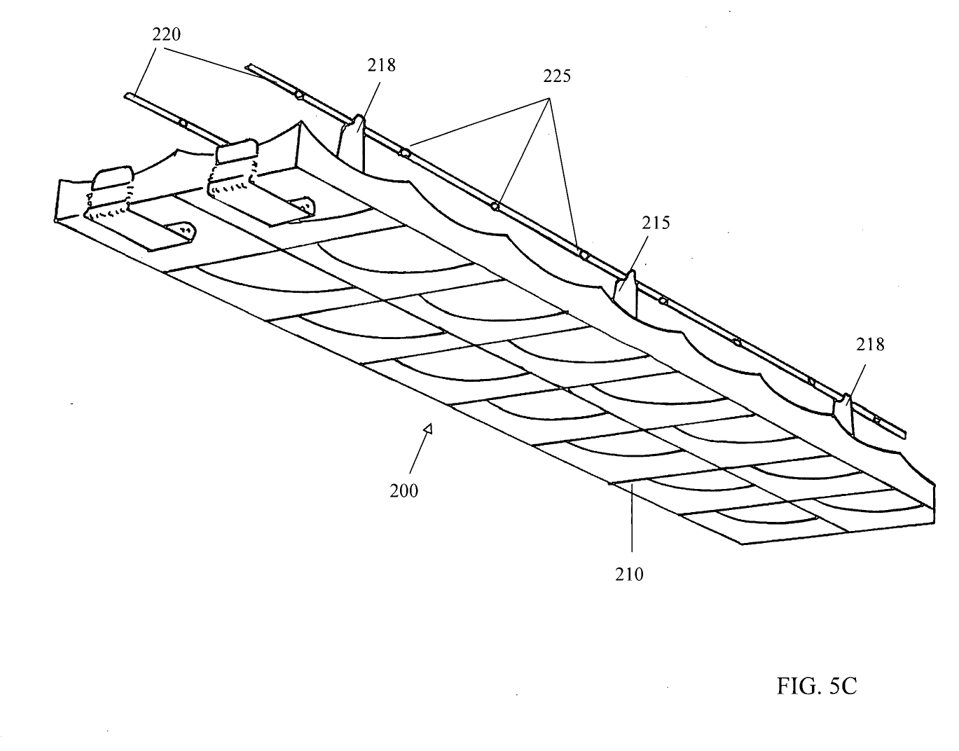

FIG. 5A presents a comprehensive view of a solar concentrator 200 after the present invention. Mirror assembly 210 comprising a plurality of curved mirror segments disposed in an array—this case two parallel sets of 8 mirror segments. A set of support structures 218 and a set of central support structures 215 located at the boundaries between mirror segments support an upper structure comprising photovoltaic assembly 220 and heat sink assembly 230.

Photovoltaic assembly 220 comprises a plurality of photovoltaic cells 225 (4 of 16 indicated) disposed at the focal point of the mirror segments and electrical connecting means such as standard FR4 printed wiring board. Photovoltaic assembly 220 may be mounted to the heat sink assembly. The parallel photovoltaic assemblies 220 are electrically connected by jumper wire 238. The end of the two photovoltaic assemblies 220 are electrically connected to output terminals 245 by jumper wires 240.

Mirror assembly 210 is comprised of a plurality of mirror segments. The mirrors may be spherical, parabolic or elliptical or some combination of these. In a preferred embodiment the mirrors are rotationally symmetric and are each fabricated according to the same optical prescription. Calculated data on a prescription for the mirrors is presented in another section of the present application. In another preferred embodiment the individual mirror segments are formed in squares with the same dimension on the longitudinal and transverse axes. Other configurations are possible within the scope of this invention. Use of a trough mirror is known in the prior art and is disadvantageous because of the low concentration ratio.

Mirror assembly 210 depicts one embodiment of a mirror assembly after the present invention. The example depicts a two-channel mirror assembly comprised of a two by eight array of mirrors. Other number of mirrors and channels are understood to fall within the scope of this invention.

As shown in the inset of FIG. 5A, three orthogonal axes of the system are defined. The longitudinal axis is the long axis of the solar concentrator. The transverse axis is the axis across the surface of the solar concentrator orthogonal to the longitudinal axis. The solar axis is the axis orthogonal to the longitudinal and transverse axes and is the axis that is aligned to point to the position of the sun.

The assembly itself may be made of any acceptable material such as ceramic, metal, or plastics such as Polycarbonate or PMMA with a suitable reflective coating such as aluminum or silver deposited thereon by techniques long known in the art. The mirror assembly may be formed of a single piece by techniques such as injection molding, casting, or stamping. The mirror assembly may be constructed of a number of pieces that are assembled into a frame during construction of the assembly. For example, each mirror may be fabricated separately, coated and then assembled into an array using construction techniques that are well known.

The underside of one single piece mirror assembly is depicted in FIG. 5B for additional clarity. Mirror assembly 210 forms the base of solar concentrator 200. Central support structure 215 and support structures 218 provide support for photovoltaic assemblies 220 and heat sink assemblies 230. Photovoltaic cells 225 (3 shown) are positioned at the focal point of the mirror segments of mirror assembly 210.

FIG. 5C provides a view of the solar concentrator of FIGS. 5A and 5B with heat sink 230 removed for additional clarity. Central support structure 215 and support structures 218 provide support for photovoltaic assemblies 220. Photovoltaic cells 225 (3 shown) are positioned at the focal point of the mirror segments of mirror assembly 210.

The material used for mirror assembly 230, central support structures 215 and support structures 218 may be a material such as PMMA or polycarbonate or alternatively some other form of plastic or a metal. In one embodiment heat sink assembly 220 and photovoltaic assembly are anchored to the center support structure 215 of FIG. 5A and held by the other support structures 218 in an arrangement that keep the assembly aligned vertically but allows the mirror assembly underneath it to expand or contract in the thermal environment without extreme stress on any of mirror assembly 210, heat sink assembly 230, photovoltaic assembly 220, center support structure 215 or support structure 218.

The range of coefficients of thermal expansion or C_{TE} of the materials that are available to create a solar concentrator system after this invention is quite varied. The consequences of these differences on a system subject to significant temperature changes between operating mode (day) and non-operating mode (night) can be profound if not provided for.

| | Coefficient of Thermal Expansion |
|---|---|
| Material | (C_{TE}) Parts per million/° C. |
| PMMA (Acrylic), cast | 81 |
| Polycarbonate | 70.2 |
| FR4 | 11 lengthwise/15 crosswise |
| Aluminum | 22.2 |
| Copper | 16.6 |
| Ceramic (alumina) | 7.1 |
| Germanium (photovoltaic substrate) | 5.9 |

PMMA and Polycarbonate are suitable materials for the manufacturing of the mirror assembly. Both materials can be molded or cast into the needed shape without the need for secondary polishing. Polycarbonate may offer some thermal and reflective coating advantage over PMMA. FR4 board is an excellent, low cost printed circuit material. It can be fabricated by a number of independent printed circuit board houses. Aluminum and copper are suitable materials for a heat sink material. Both can transport heat very well. Copper offers a second advantage in that it is an excellent conductor as well as heat sink and may be used as such in some embodiments of this invention. Copper offers a third advantage in the excellent matching of its C_{TE} to that of FR4 board. (This is expected since circuit traces on a printed circuit board are most often made of copper. The choice between ceramic and Germanium as substrate for the photovoltaic cell is largely a matter of taste and cost. The parts in production are to be made as small as practicable so any mismatch to FR4 board will have minimal effect.

Calculations indicate that a system of 8 mirror segments with an overall length of 360 millimeters results in a change between the aluminum/copper components and the PMMA/Polycarbonate components along the longitudinal axis of 1 to 2 mm. As noted elsewhere in this application this is significant for two reasons. First, the spot at the focus of the mirror segments is not infinitely small, being typically 0.5 mm, and, second, the cost per unit area of the photovoltaic material must be considered when designing a system to product electricity at the lowest cost per kilowatt.

One solution to the problem of the mismatch between the materials for the mirror assembly and the heat sink/printed circuit assembly/photovoltaic assembly is to adjust the size of the photovoltaic assembly so that some part of each photovoltaic cell is illuminated by the concentrated reflection of its associated mirror segment the over the entire operating temperature range of the solar concentrator. In a preferred embodiment the heat sink / printed circuit assembly/photovoltaic assembly is fixed to a support near the center of the longitudinal axis of the mirror assembly and the other supports are disposed so as to hold the assembly in place but so as not to prevent it from slipping slightly as the various materials expand or contract at their normal rate in response to changes in environmental temperature. In FIG. 5A the middle support structures are so marked as an example. Taking this approach does not reduce the mismatch but does reduce its effects over the alternative of fixing one end of the assembly to the support for that end. This still requires that the photovoltaic cells further from the center support be somewhat enlarged to allow the concentrated reflection of the associated mirror segment to be converted to electrical power but less so than in the other examples. In an alternative embodiment the mirror assemblies may be fabricated from aluminum and then coated with a specular reflective surface.

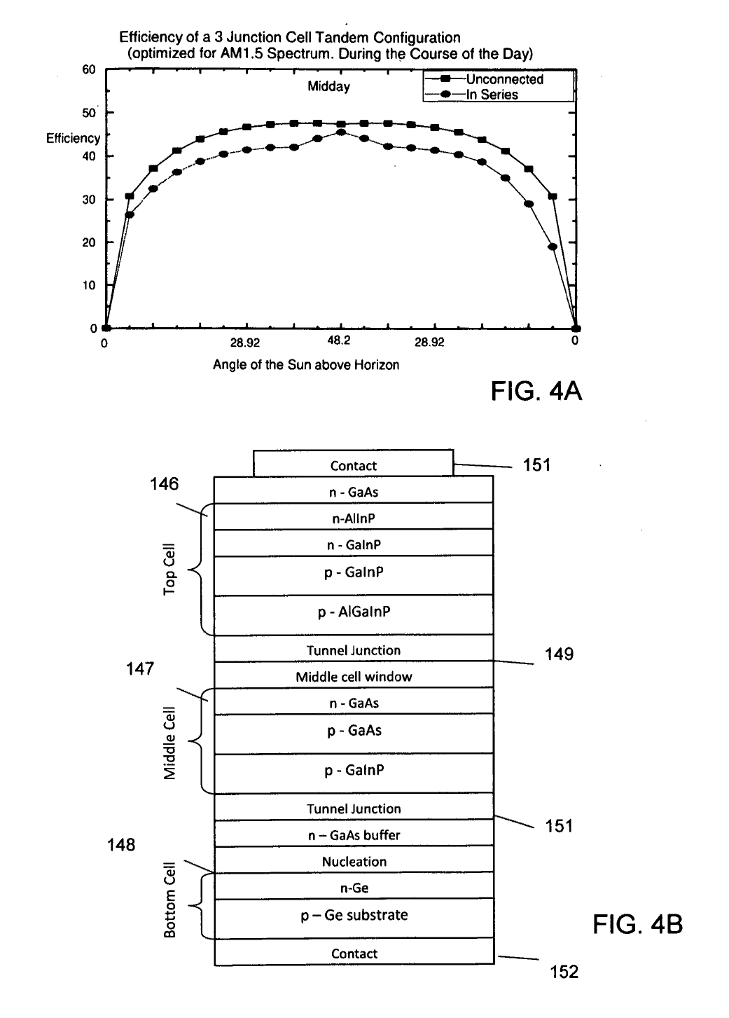

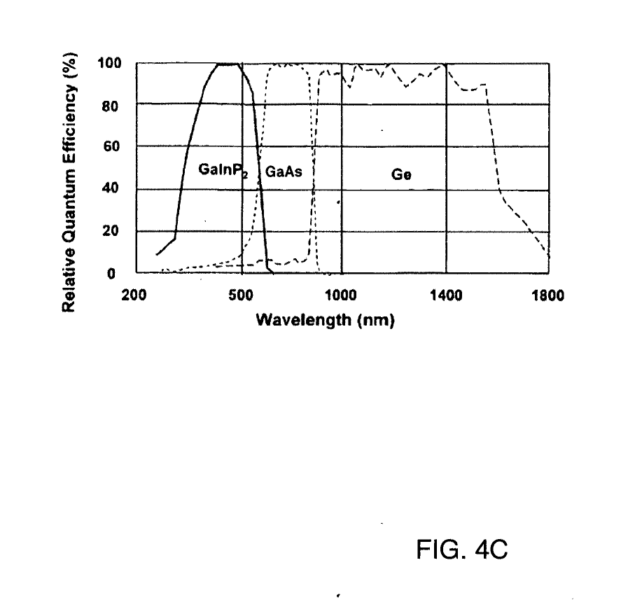

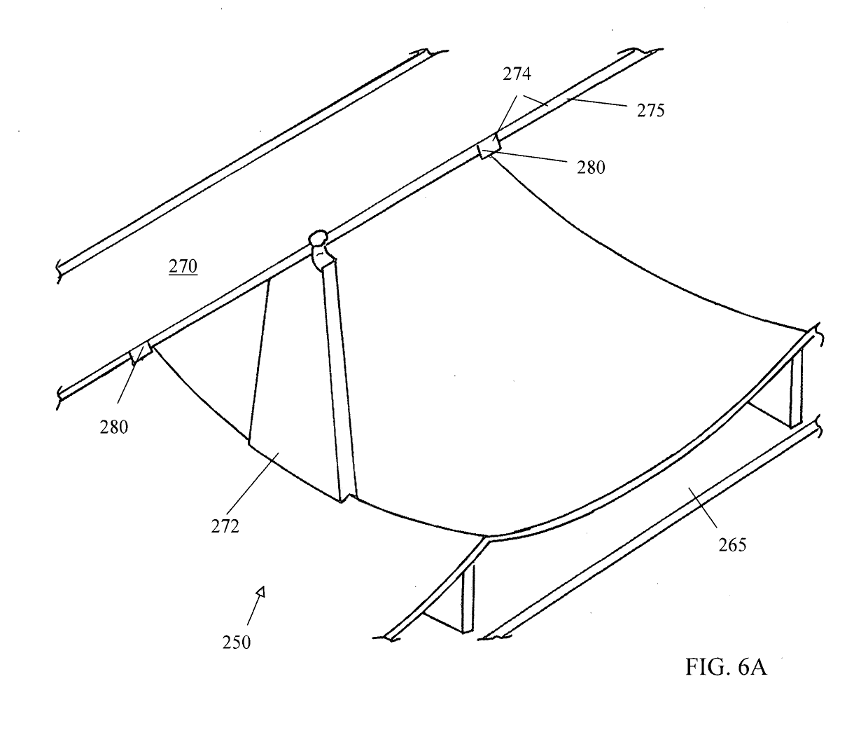

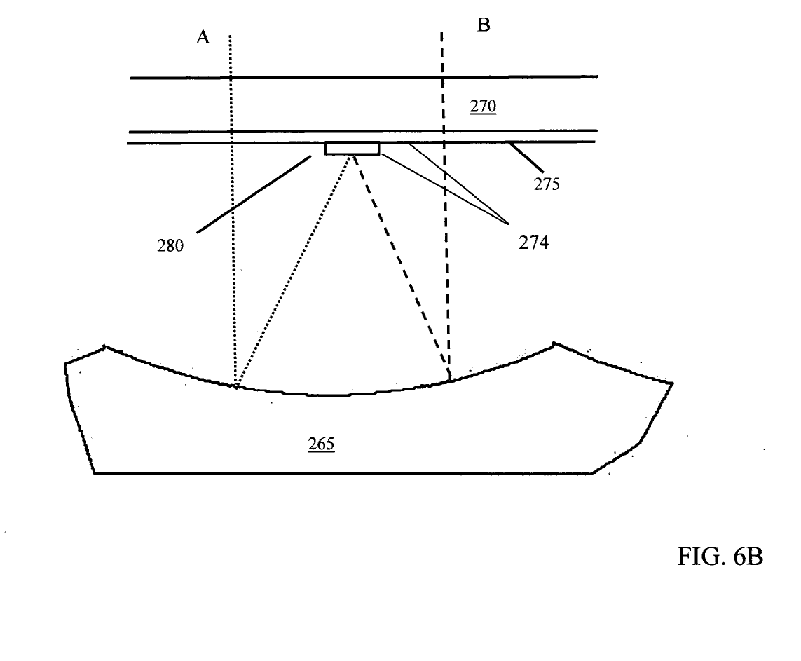

FIG. 6A depicts a detailed view 250 of mirror segment 265 of a mirror assembly after FIG. 4A, support structure 272, heat sink 270 and a photovoltaic assembly 274 comprising circuit board 275 with photovoltaic cell 280 affixed thereto. Support structure 272 is used to hold heat sink assembly 220 and photovoltaic assembly 274 in the correct position optically and to secure it mechanically.

FIG. 6B presents a sectional side view of the segment of FIG. 6A. Mirror segment 265 receives solar radiation beams A and B and reflects those beams to photovoltaic cell 280. The curved shape of mirror segment 265 may be parabolic or some other appropriate shape. Photovoltaic cell 280 is affixed electrically and mechanically to printed wiring board 275 using conductive epoxy or solder surface mount techniques widely known in the art. Photovoltaic assembly 274 comprises photovoltaic cell 280 and printed circuit board 275. Photovoltaic assembly 274 is affixed to heat sink assembly 270 using an insulating or conducting epoxy depending on a series or parallel electrical configuration of the photovoltaic assembly.

Design of the mirror segments is a very important consideration for the present invention. In one embodiment the mirrors are parabolic cross section with a rotationally symmetric cross section. The table below presents one possible prescription for such a mirror set.

| | | | | | Vertex |
|---|---|---|---|---|---|
| Mirror | | | Radius of | | of Mirror |
| Seg- | Longitudinal | Transverse | Curvature | Conic | Relative |
| ment | Length | Width | c | Constant k | to PV z |
| All | 45 | 45 | 58.883 | −0.964 | 29 |

| | | |
|---|---|---|
| All dimensions are in millimeters | Constant | Millimeters |

The description of the curvature of the mirror is based on the Surface Formula:

$$z = \frac{{cr}^{2}}{1 + \sqrt{1 - ( 1 + k ) {c}^{2} {r}^{2}}} + {\sum }_{i = 1}^{12} {α}_{i} {r}^{i}$$

wherein
z=height y-axis (dependent variable)
r=horizontal x axis (independent variable)
c=radius of curvature
k=conic constant
αᵢ=higher order constant, in this case αᵢ=0

Optical CAD design and analysis software programs such as Zemax™, ASAP and Code V™ may receive data in this or similar formats and, through computational analysis, provide a detailed understanding of the important performance factors of an optical description such as optical efficiency (throughput), aberration, coma etc. Zemax™ may also calculate a solution based on programmed constraints.

In the present application (redirection and focusing of solar radiation) solar radiation is a distributed source subtending approximately 0.5° at a great distance, thus rendering the illumination effectively collimated. Calculations in Zemax™ confirm that the effective focal distance of a reflective curved mirror is equal to c/2 or half the radius of curvature when the illumination is sufficiently collimated. In some instances the actual focal distance may be slightly shorter than the effective focal distance to overcome the effects of aberration.

The aperture blocking cause by the presence of the heat sink and photovoltaic assembly is illustrated in FIG. 6B. Rays of solar radiation A and B must pass by the heat sink and photovoltaic assembly to impinge on the mirror segment and then be reflected to the photovoltaic cell. Since solar radiation cannot pass through these items it is essential that the thickness of these items along the transverse axis be as thin as possible. This thickness will have a direct effect on the concentration ratio of the overall system because it effectively reduces the transverse dimension of the mirror segments of the mirror assembly by its thickness. In the example previously given a 45 mm wide mirror segment would be effectively reduce to 43 mm wide if the heat sink/printed circuit assembly/photovoltaic assembly is 2 mm wide. This reduces the effective aperture from 45 mm by 45 mm or 2025 square mm to 45 mm by 43 mm or 1935 sq mm—a reduction of 4.5%. A further increase in this transverse axis dimension to 3 mm would results in an overall reduction of 6.7%. Thus the need to make this as thin as possible is clear because the reduction in the effective aperture directly correlates to a proportionate reduction in the electrical power the photovoltaic cell can generate.

The minimum width of a printed circuit assembly manufactured of FR4 board—a commonly used material—is approximately 1.65 millimeters: This is a further need to provide a path from the photovoltaic cell to the heat sink to insure that heat is dissipated to the degree necessary to preserve the proper functioning of the photovoltaic cell.

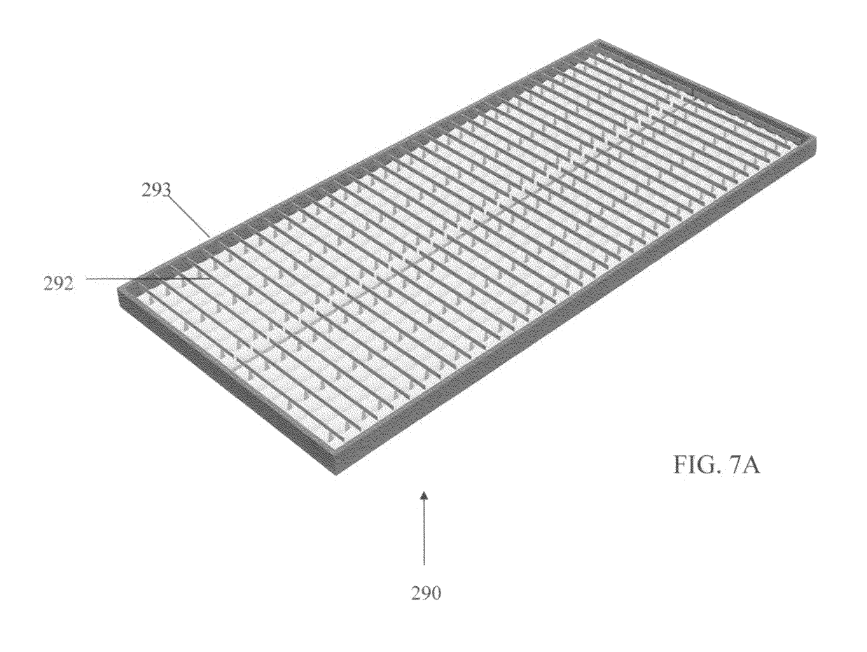

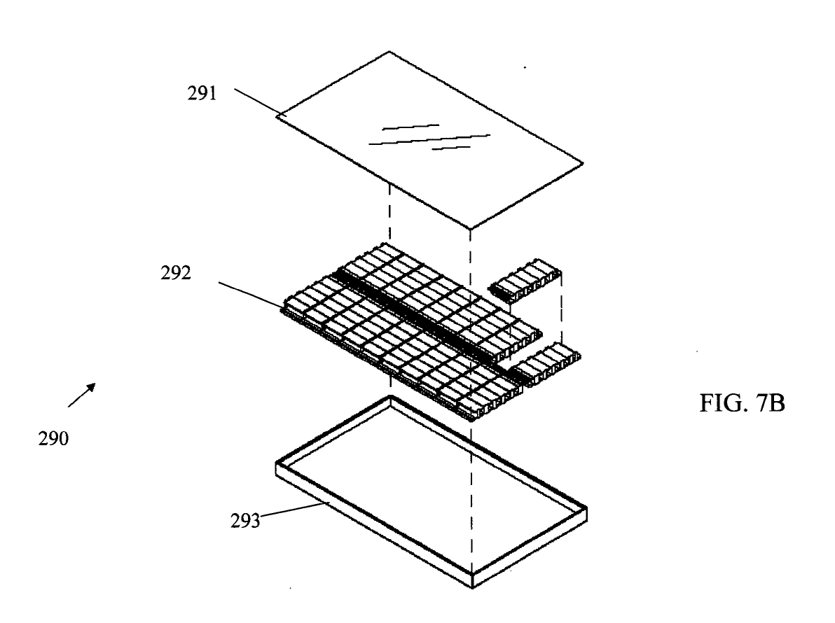

FIG. 7A depicts an isometric view of a panel assembly 290 comprising an arrangement of a plurality of solar concentrator assemblies 292 mounted in a frame 293 and with a cover glass 291 (not shown). The panel assembly may be fabricated so as to ease the task of connecting the individual solar concentrator assemblies to the wiring of the panel assembly. In one embodiment that panel assembly includes fixing means to enable operation of the panel assembly at the angles required by the solar tracking mode.

FIG. 7B presents an expanded image of panel assembly 290. A plurality of solar concentrator assemblies 292 is mounted into frame 293 and cover glass 291 is placed thereon to form a unit sealed against weather and blowing dirt and the like.

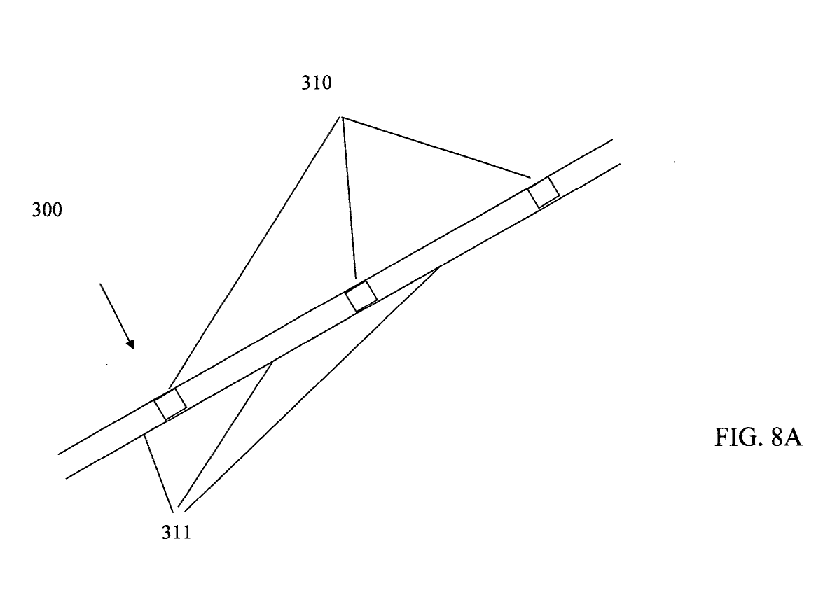

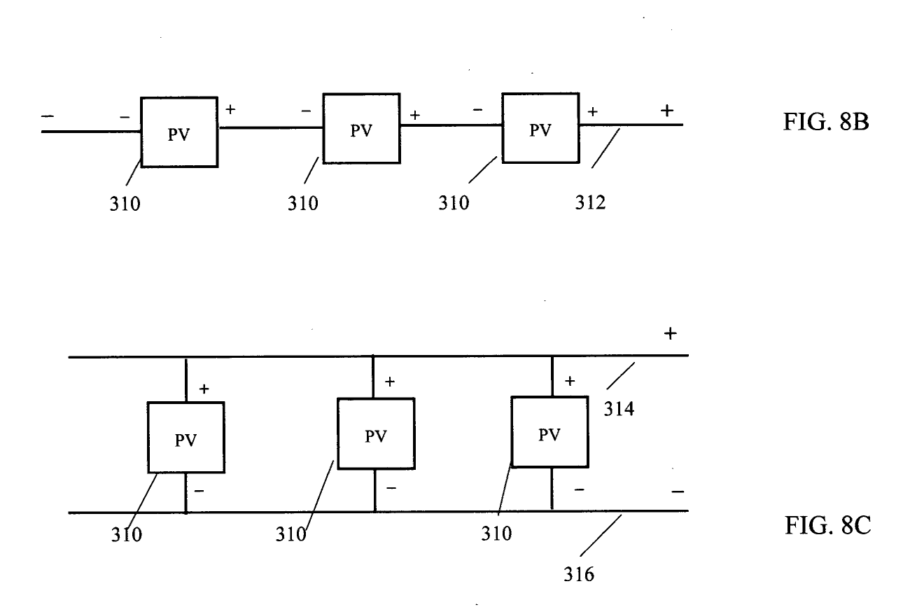

FIG. 8A depicts a simplified view of photovoltaic assembly 300. Individual photovoltaic cells 310 are mounted to printed circuit board 311. Printed circuit board 311 may be fabricated of material such as FR4 board. The photovoltaic cells 310 may be wired in series or in parallel as is disclosed in the following paragraph.

A solar concentrator after this invention must include collection circuitry that allows the electrical power generated thereby to be harvested. The individual triple junction PV cells may be wired in series or in parallel or a combination thereof. FIG. 5A includes a drawing of a set of Jumper wires that are representative of either the parallel or the series configuration. Schematics of the two alternatives are provided in FIGS. 8B and 8C. FIG. 8B depicts the schematic of a set of photovoltaic cells 310 wired in series through a series of electrical connections 312. FIG. 8C depicts the schematic of a set of photovoltaic cells 310 wired to parallel wiring busses 314 and 316. Each configuration offers advantages and disadvantages. For example, a series configuration allows the system to operate at higher voltage and lower current than the parallel configuration but suffers from the defect that the failure of a single electrical connection will induce the failure of the entire voltage collection system in that series.

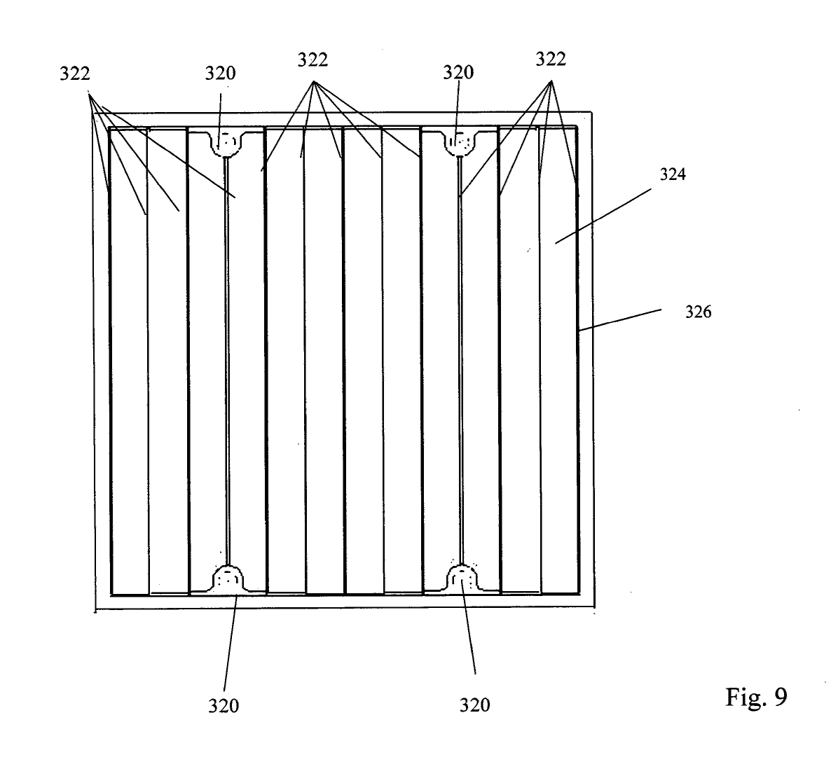

FIG. 9A depicts a triple junction solar cell comprising three separate semiconductor layers, each traversed by a set of collecting filament wires on the surface and with a collecting structure on the based. The filament wires are connected in parallel to four electrical contact points. In a reliable installation all four contracts are used so as to allow the lowest resistance losses from the current generated in the PV cell.

The depicted triple junction solar cell is typical of a type available on a commercial basis from companies such as Encore or Spectrolab. These devices are typically standard photovoltaic materials packaged to purchaser specifications for a particular application by the manufacturer. This approach provides a good tradeoff by providing companies with access to components, at least part of which is the result of a high volume process. The Encore triple junction cells are reported by their manufacturer to achieve up to 39% conversion efficiency under concentrated illumination.

A driving factor behind selection of a mechanical design for a photovoltaic cell for the present invention is the need to be able to attach the cell to a printed circuit assembly that also supports achieving the other design requirements such as high concentration ratio. Inspection of FIGS. 5A, 5B, 6A and 6B reveal a structure wherein the photovoltaic cell is blocking part of the aperture of the mirrors on the mirror assembly. The necessity is to minimize any blockage of the aperture caused by the photovoltaic cells, the printed circuit assembly and the heat sink assembly since all are arrayed over the mirror assembly. This requires that the elements be made as narrow as possible along the transverse axis.

The printed circuit assembly is a relatively simple structure of a type available from independent board manufacturing houses. FR4, a commonly used material, is suitable for this application. The assembly may have two traces, one for the positive voltage side and one for the negative voltage side. The actual wiring schematic may be either a parallel or a series implementation. In one embodiment the printed circuit assembly may have a single trace and the heat sink may be used as a second trace.

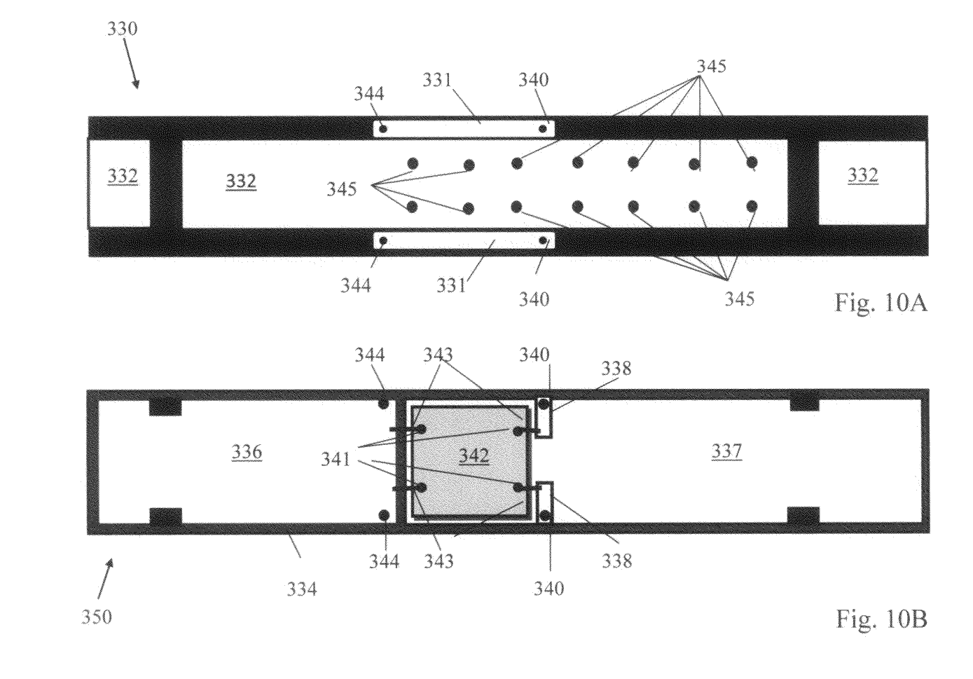

FIGS. 10A and 10B depicts one embodiment in which a photovoltaic cell 342 (after FIG. 9A) may be mounted onto printed circuit board both mechanically and electrically. FIG. 9A, item 330, represents the upper surface of a printed circuit board that may be affixed to a heat sink as previously described. FIG. 9B represents the lower surface 334 of the same printed circuit board. Photovoltaic cell 342 is mounted to circuit board 334 on copper trace 337. The left side electrical contacts 341 of photovoltaic cell 342 are connected to copper trace 336 by jumper wires 343. The right hand side electrical contacts 341 are connected to copper traces 338 by jumper wires 343. Copper traces 338 are connected to copper trace 331 of FIG. 10A through via 340. Copper trace 331 is connected to copper trace 336 through via 344. Thus the base of photovoltaic cell 342 is connected to copper trace 337 while all the top trace connections are connected to copper trace 336. The pattern repeats itself and effectively wires the photovoltaic cells in series.

One additional feature of the printed circuit board of FIGS. 10A and 10B is a provision for thermal management. Vias 345 on copper trace 332 of FIG. 10A may be filled with a thermally conductive material to facilitate the transfer of heat from photovoltaic cell 342. Although copper trace 332 is not intended to be electrically active it can contribute to the spreading of heat.

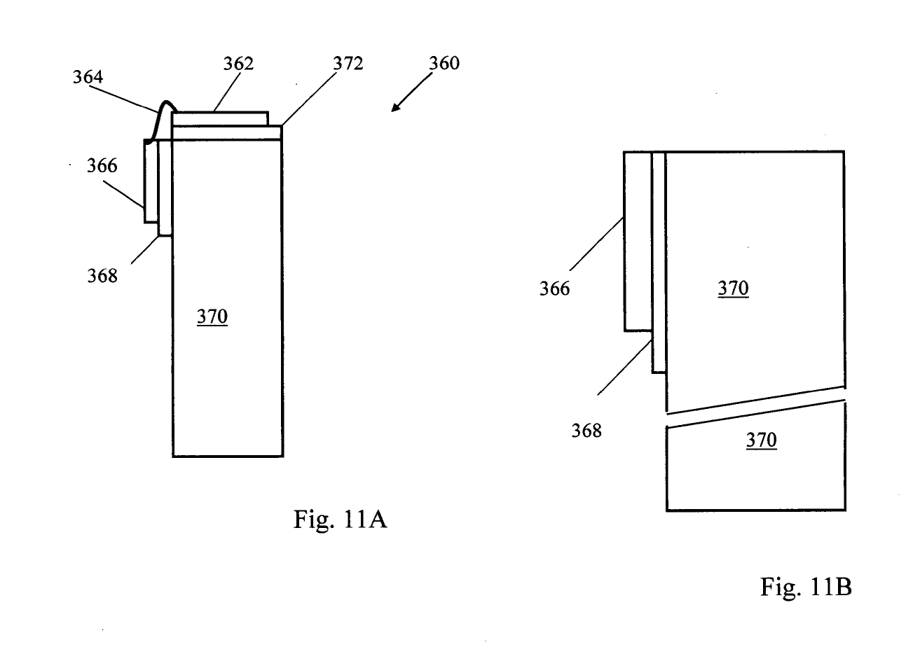

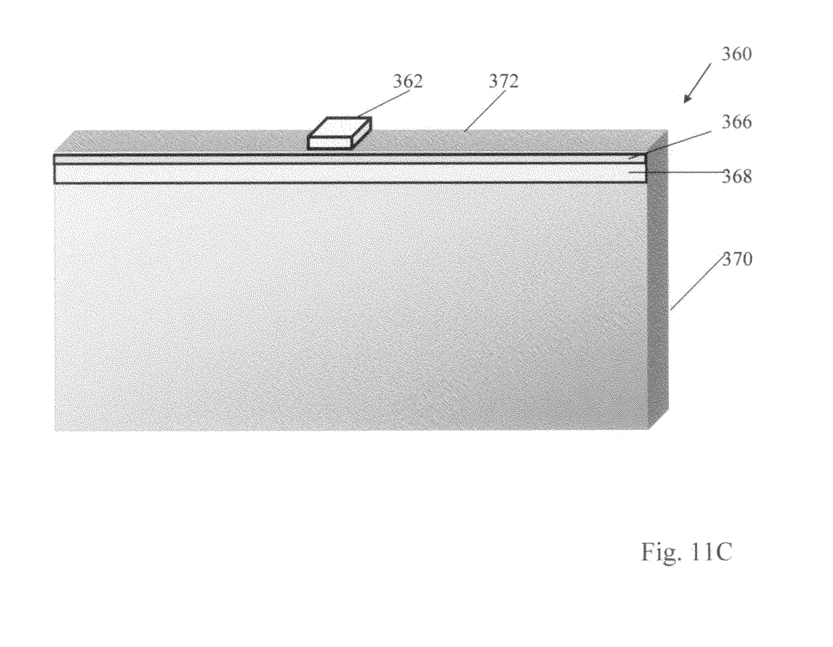

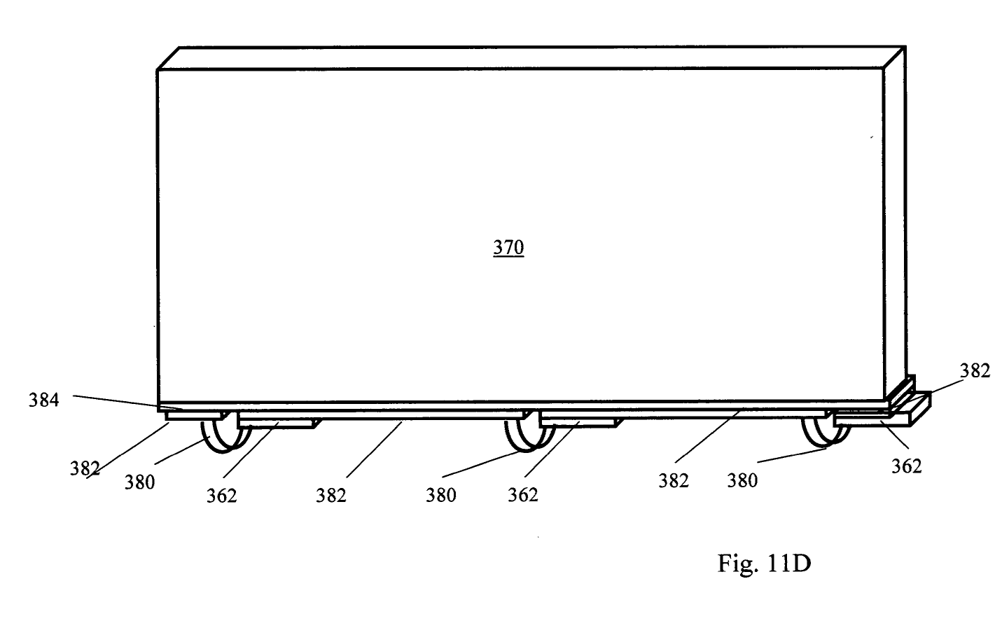

FIG. 11A presents a side view of an alternative means of wiring a set of photovoltaic cells in parallel. In this example heat sink assembly 370 is fabricated of an electrically conductive metal such as aluminum or copper. Photovoltaic cell is affixed to heat sink 370 by a conductive adhesive 372. Electrically insulating layer 368 is affixed to heat sink 370, and copper trace 366 is affixed to insulating layer 368 such that it is electrically isolated from heat sink 370. The surface electrical connection of photovoltaic cell 362 is connected to copper trace 366 by jumper wire 364. FIG. 11B provides a more detailed view of heat sink 370, insulating layer 368and copper trace 366, indicating the electrical isolation of copper trace 366 from heat sink 370.

FIG. 11C presents a perspective view of the wiring arrangement after FIG. 11A. Photovoltaic cell 362 is electrically connected to heat sink 370 by conductive layer 372. Copper trace 366 is isolated from heat sink 370 by insulating layer 369. The surface electrical connection of photovoltaic cell 362 is connected to Copper trace 366 by jumper wire 364 (not shown).

FIG. 11D presents an alternative means of arranging the printed circuit boards. Printed circuit boards 382 are affixed to heat sink by adhesive layer 384. Photovoltaic cell 362 is affixed to printed circuit board 382 electrically and mechanically. Surface electrical contacts of photovoltaic cell 362 are connected to the adjacent printed circuit board 382 by jumpers 380. In one embodiment adhesive layer 384 may be an insulator. Photovoltaic cell 362 is electrically connected through the base contact to a copper trace on printed circuit board 382. The surface electrical contacts are connected by jumpers 380 to the surface of adjacent printed circuit board 382. Thus all photovoltaic cell 362 are placed in series.

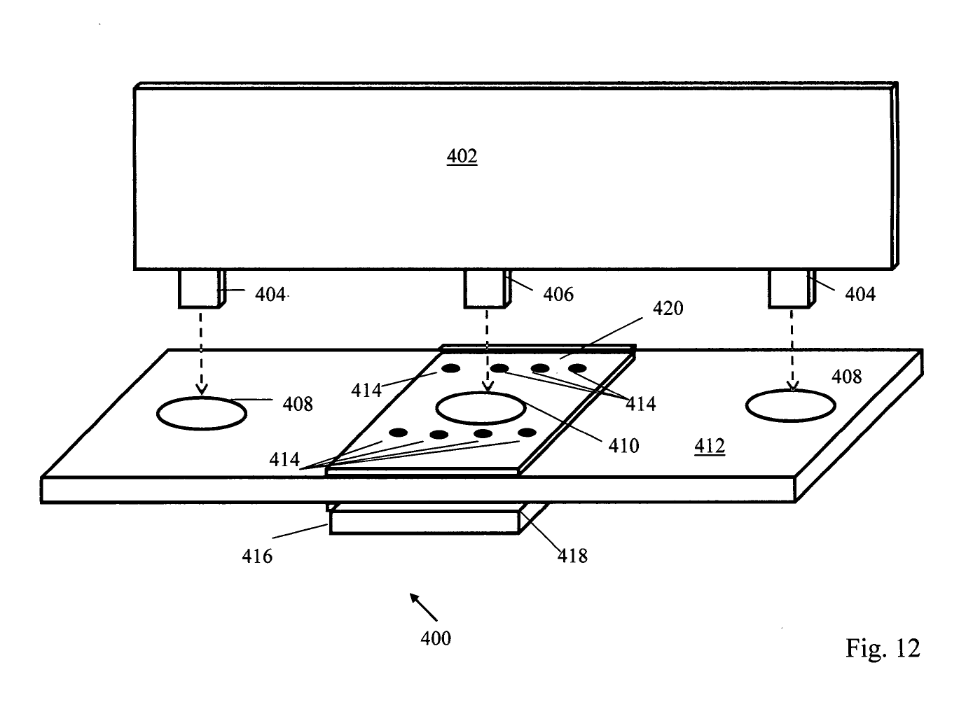

FIG. 12 depicts an alternative means of fixing a heat sink to a photovoltaic cell wherein a copper heat sink “fin” 402 is attached to printed circuit board 412 by means of tines 404 and 406. Tines 404 are attached through apertures 408 not in close proximity to photovoltaic cell 416, and tine 406 is attached through aperture 410 located at the back of photovoltaic cell 416. Photovoltaic cell 416 is affixed to a conductive layer 418 which is in turn affixed to printed circuit board 412. A second layer 420 which may be conductive is affixed to the opposite side of printed circuit board 412. Optionally via 414 may be established that are filled with thermally conductive material to improve the transfer of heat to heat sink 402. The heat sink “fin” 402 may be continuous to form a parallel type of electrical output or discontinuous between each die to allow for electrical isolation thereby enabling series connection. A combination of the two configurations enabling the series connection of pairs of photovoltaic cells is conceived.

Heat sink 402 is functionally needed to dissipate heat that is generated within photovoltaic cell 416 when it is generates electrical Power in response to illumination by solar radiation. Some of the heat results from absorption of some of the radiation that impinges on it. Heat sink 402 is preferably made of a single piece of metal. The metal may be cast or stamped as appropriate. Heat sink 402 has no optical properties although it is important that it be designed and fabricated so as to cause the least possible aperture blocking. Suitable materials include copper and aluminum although other materials may be equally suitable.

Copper is also an excellent conductor of electricity. In one embodiment the heat sink may also act as a conductor for electricity generated by the photovoltaic cells. This is particularly useful in reducing the size of the printed circuit board since that board now needs one less conductor internal to it. Alternatively this can be used to allow a larger trace inside the printed circuit board in the event the current flow it is required to handle is high enough to be of concern.

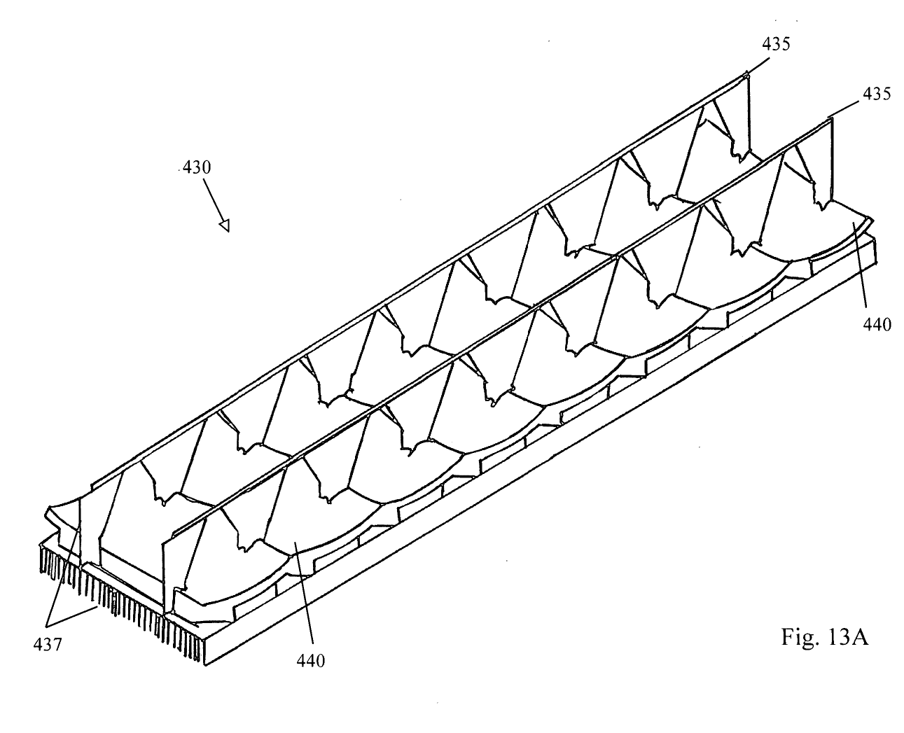

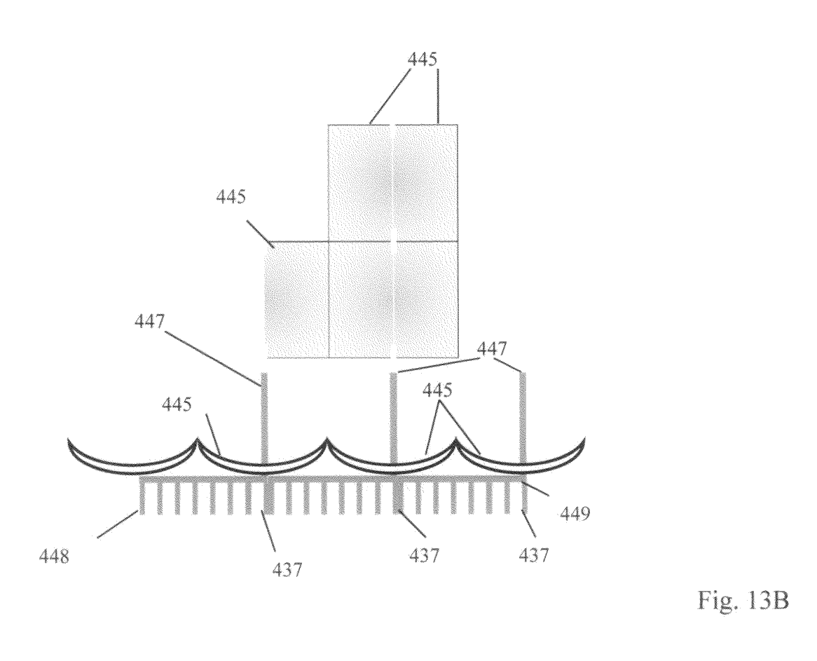

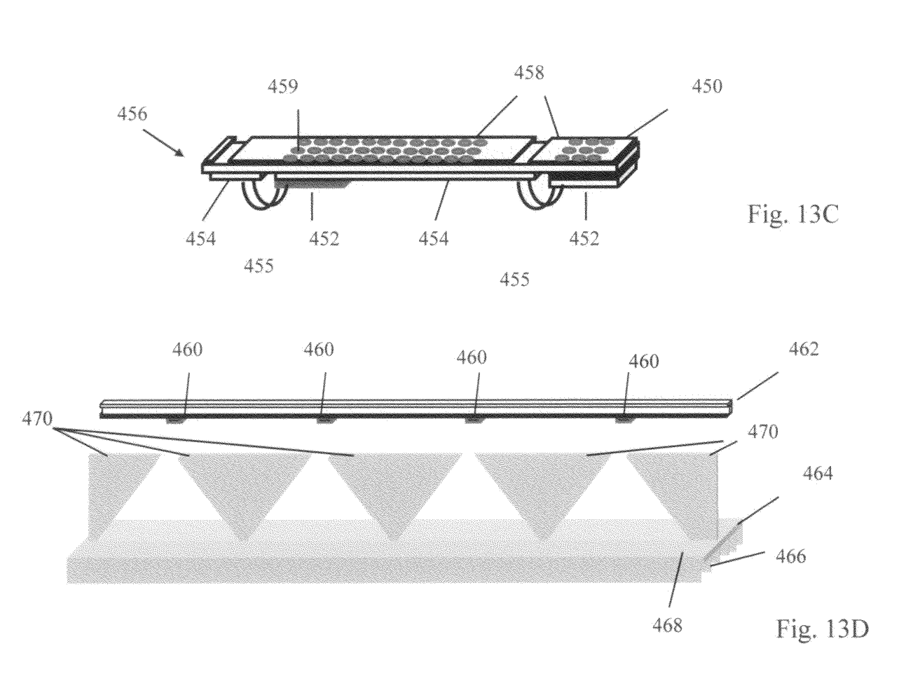

FIG. 13A depicts an alternative heat sink arrangement. Solar concentrator assembly 430 comprises mirror assembly 440, photovoltaic assembly 435 and heat sink 437. Heat sink 437 is fabricated such that part of the heat sink forms the riser structures previous noted. Photovoltaic assembly 435 may be affixed to heat sink 437 by use of a thermally conductive adhesive. Heat sink assembly 437 may be formed by extrusion a suitable metal such as aluminum or copper along the longitudinal axis of the heat sink. After the extrusion process is completed, the clear apertures for the photovoltaic cells (not shown) of photovoltaic assembly 435 may be formed by a punch process. Other means of constructing a heat sink will be obvious to a practitioner of ordinary skill in the art. Heat sink 437 may form the support structure for solar concentrator assembly 430.

FIG. 13B depicts a plane view of segments 445 of mirror assembly 440 and an end view of combined mirror segments 445 and heat sink 448. Heat sink 448 comprises riser segment 447, base 449 and radiating fins 437. In one embodiment heat sink 448 is formed as a single piece. Mirror segments 445 may be formed as an assembly of mirror segments as described in this application. In one embodiment mirror segments 445 may be formed in half mirror sections along the longitudinal axis to enable easy mating of mirror segments 445 with heat sink 448.

Referring to FIG. 13B, rather than constructing the mirror assembly as a unitary piece it is now constructed in two halves that are to be mounted on either side of the riser assembly. The support structures of FIG. 13A are not separately constructed and do not form a part of the mirror assembly. The mirror assembly half-mirror segments may be manufactured to the previously disclosed optical prescription. The center of the half mirror segments are aligned with the riser so that the center of the mirror along the longitudinal axis is place midway between the bottom of the riser segments as seen in FIG. 13A. This is necessary to insure that the focal point of the two mirror assembly half segments is at the photovoltaic cells mounted to the photovoltaic assembly. In like manner the other variations are possible, including a rotationally symmetric parabolic cross section. Note that the center of rotation is at the edge of the half mirror segment at a point substantially under the photovoltaic cell associated with that half mirror segment. The base of the heat sink assembly forms a mounting structure for the two mirror assembly half segments. In one embodiment the heat sink assembly extrusion includes features that can capture alignment structures that form a part of the half mirror segments of the mirror assembly to secure the segments in their proper place.

Mounting and alignment of mirror segments on heat sink 448 may be accomplished in several ways. First, the half-mirror segments of the mirror assembly may be cast pieces of plastic that are subsequently coated with a metallic or dielectric coating to insure reflectivity at the proper point. The segments may be molded or cast with appropriate tongue and groove fittings so that the parts on either part of the heat sink riser may be aligned with one another. Additionally the tongue and groove fittings may easily be designed so that only one mould design is required. Additional alignment features may be placed in the mold so that the mirror assembly half-mirror segments snap into holding features in the heat sink extrusion.

FIG. 13C depicts photovoltaic assembly 456 suitable for the present invention. Photovoltaic cell 452 is affixed to circuit board 454. Heat spreader 450 is affixed to the surface of printed circuit board photovoltaic cell 452 opposite photovoltaic cell 452. Vias 458 are filled with a thermally conductive material to facilitate the movement of heat from photovoltaic cell 452. In one embodiment vias 458 extend through printed circuit board 454 to facilitate transfer of heat to a heat sink assembly (not shown) The surface collection terminal (not shown) of photovoltaic cell 452 is connected to adjacent printed circuit board 454.

FIG. 13D depicts the mating of photovoltaic assembly 462 to heat sink 468. Heat sink 468 comprises riser assemblies 470, base 464, and cooling fins 466. Photovoltaic assembly 462 comprises photovoltaic cells 460. Photovoltaic assembly is mated to risers 470 so that photovoltaic cells 460 are positioned at the focal points of a mirror assembly (not shown). An adhesive layer (not shown) may be used to affix photovoltaic assembly 462 to risers 470. The adhesive layer may be electrically conductive or not as required for the electrical function of photovoltaic assembly 462. The adhesive layer should be thermally conductive for best functionality. Suitable adhesive materials are commonly available from companies such as Dow Corning and Epotek.

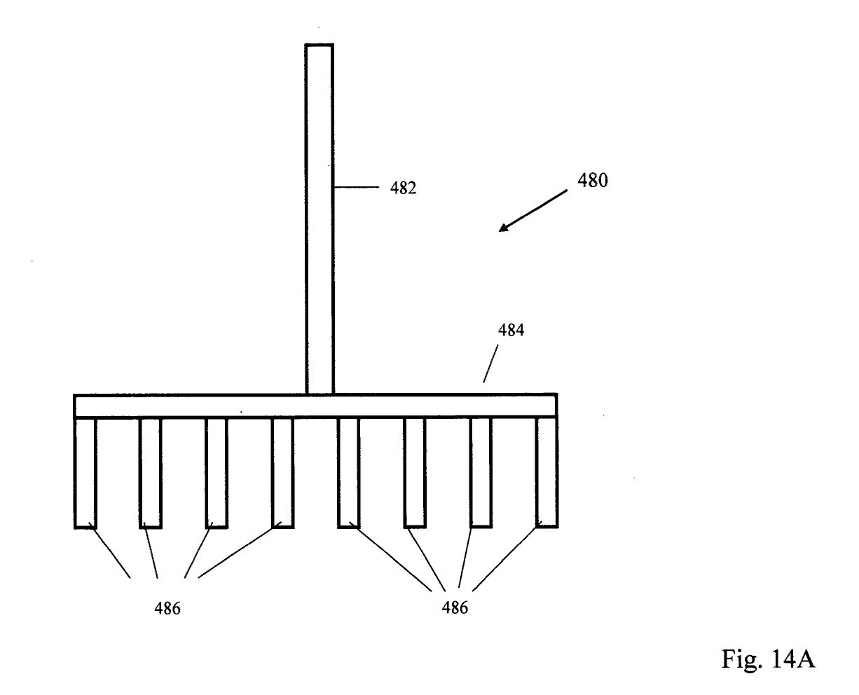

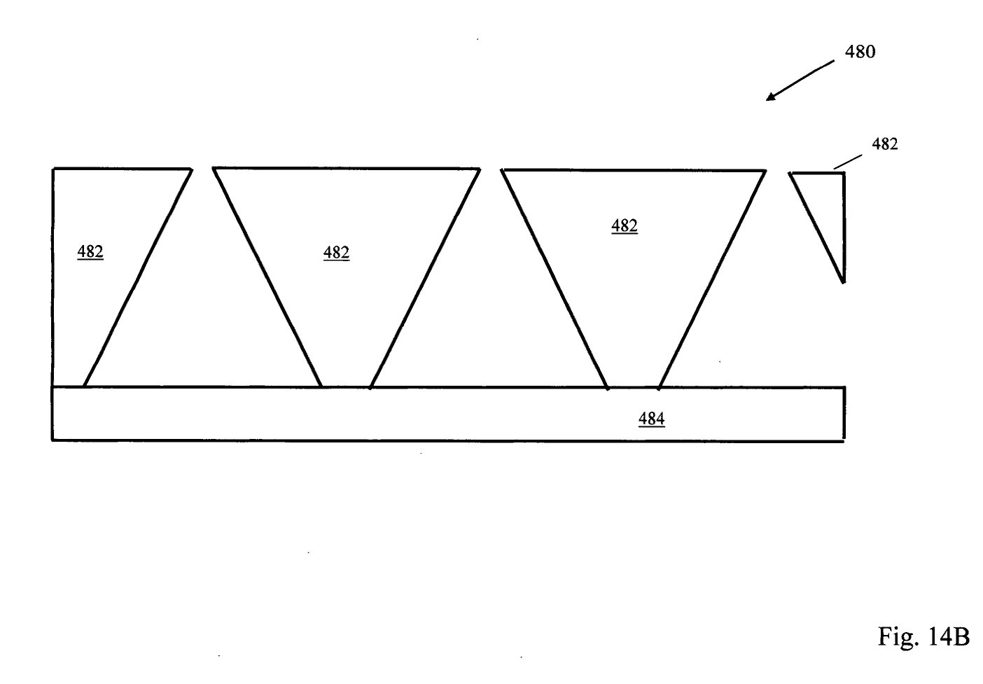

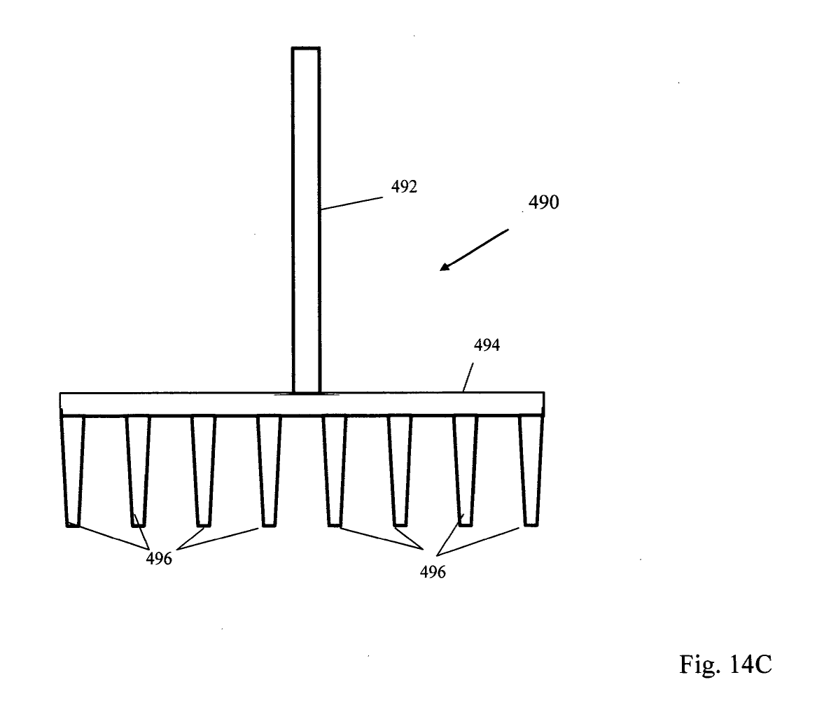

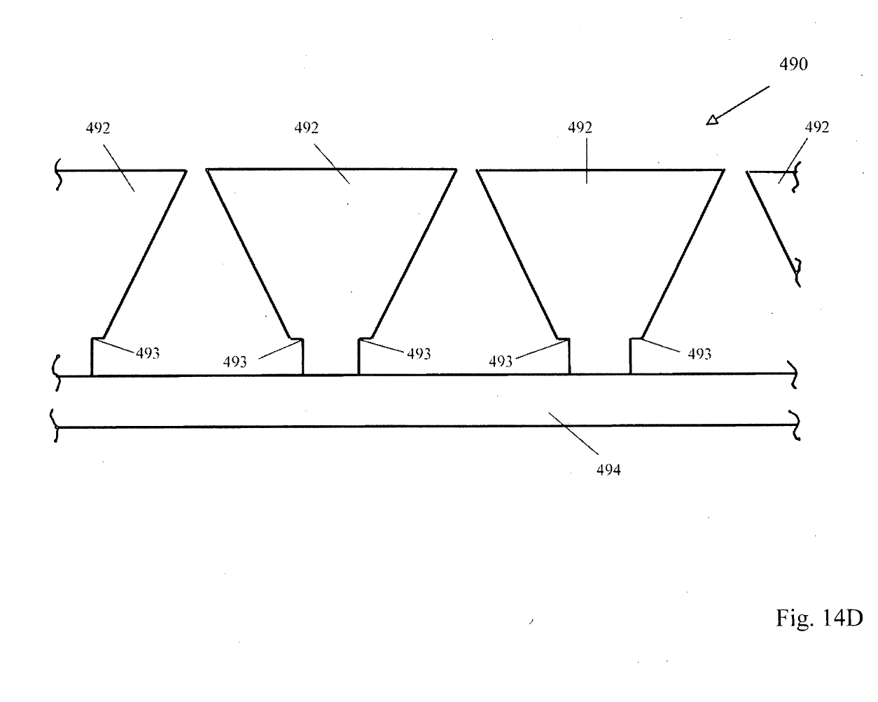

FIG. 14A depicts an end view of heat sink 480 according to the present invention. Heat sink 480 comprises riser 482, base 484 and cooling fins 486. Heat sink 480 is preferably fabricated of a metal with good heat transfer properties such as aluminum or copper. Because the cross section is constant heat sink 480 may be fabricated efficiently by extrusion. FIG. 14B depicts a side view of heat sink 480 wherein clear apertures have been formed between adjacent risers 482. The apertures may be formed by punching or other means such as sawing.

FIG. 14C depicts an end view of heat sink 490. Heat sink 490 comprises riser 492, base 494 and taper cooling fins 496. There may be several advantages to this approach. It may be easier to extrude and cooling fins 496 have slightly more radiating area that comparable rectangular fins and less material is required making the system lower weight and lower cost.

FIG. 14D depicts a side view of heat sink 490 wherein the punch space between risers 492 which substantially clears the light path from the mirror to the photovoltaic die and which includes an alignment feature 493 to facilitate the installation of a mirror assembly (not shown). In one embodiment base 494 forms a support for the mirror assembly (not shown). This feature is referenced in the text for FIG. 13B.

One important goal for all photovoltaic systems is increased conversion efficiency. The developers of triple-junction photovoltaic cells regularly devote substantial budget and effort to try to reach higher levels of efficiency. One alternative is to use a plurality of single junction materials with a plurality of band gaps so that different components of the solar spectrum are harvested by correspondingly matched semiconductor bandgap energies. This requires that the single junction photovoltaic cells be wired separately so that the limitations of series connected triple junction tandem cells materials are avoided. This in turn requires that some sort of solar spectrum wavelength separating means be used.

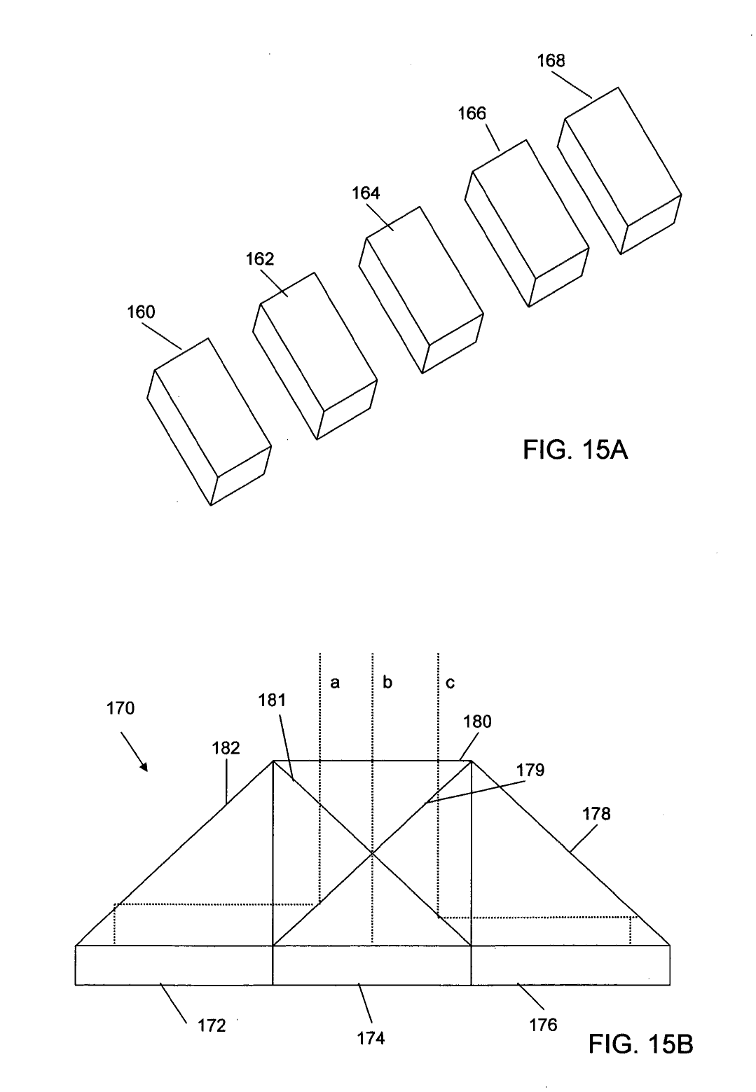

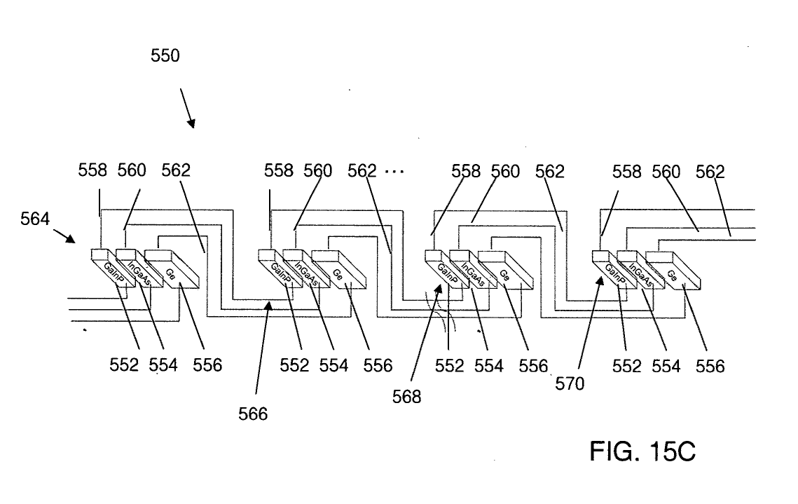

FIG. 15A depicts a series of single junction cells 160, 162, 164, 166 and 168 of different materials of correspondingly different bandgap functions and peak efficiency wavelength ranges. It is convenient to arrange the single junction cells onto a single printed circuit board (not shown), thereby forming a single junction photovoltaic assembly. The positioning of the cells on a printed circuit board depends completely on the means used to separate the colors. In one embodiment of the present invention three single junction photovoltaic cells are ordered according to the following table.

| Material | Peak Efficiency Wavelength Range |
|---|---|
| GaInP₂ | 0.400-0.650 microns |
| GaAs | 0.650-0.850 microns |
| Ge | 0.850-1.550 microns |

Arranging the single junction cells according to wavelength allows the use of known optical devices such as holograms or prisms to separate solar radiation into its constituent spectra. Other color separating optics are known in the art.

In one embodiment the single junction photovoltaic cells are fabricated from quantum well materials such as Indium Gallium Nitride sandwiched between two layers of gallium nitride as this affords greater collection efficiency.

FIG. 15B depicts one means for separating solar radiation into constituent spectra. Optical structure 170 comprises color separating cube 180, reflective prism 182 and 178, and single junction cells 172, 174 and 176. Color separating cubes using thin film optical filters are known from usage in various liquid crystal projectors. The diagonal surfaces within the cube are coated with dichroic films 179 and 181 designed to pass one range of wavelengths and reflect another range of wavelengths. Obviously the two diagonal surfaces have coatings tuned for different wavelengths. Ray a is reflected by dichroic coating 179 to prism 182 where it is further reflected by a similar dichroic coating on the diagonal surface to photovoltaic cell 172. Ray c is reflected by dichroic coating 181 to prism 178 where it is reflected again by a similar dichroic coating on the diagonal surface to photovoltaic cell 176. Ray b is not reflected by either dichroic coating within color separating cube 180 and passes directly to photovoltaic cell 174.

One limitation of this approach is that the path length for ray b is shorter than the path length for ray a and ray c. This means that either ray b will be in focus or ray a and ray c will be in focus. It is possible to design a system where all three rays are out of focus by equal amounts but this will in turn lower the concentration ratio of a solar concentrator using this approach. It also increases the size of the single junction photovoltaic cells.

FIG. 15C presents a schematic of a wiring diagram 550 for a set of three different single junction photovoltaic cells. Cell groups 1, 2 , 3, and 4 each comprise a set of three different single junction photovoltaic cells. In one embodiment single junction photovoltaic cell 552 is fabricated from a Gallium Indium Phosphide material, single junction photovoltaic cell 554 is fabricated from an Indium Gallium Arsenide material, and single junction photovoltaic cell 556 is fabricated from Germanium. Single junction photovoltaic cell 552 from cell group 1 564 is connected in series to single junction photovoltaic cell 552 in adjacent cell group 2 566 by wire 558. In turn single junction photovoltaic cell is connected in series to single junction photovoltaic cell 552 in cell group 3 568 by wire 558. Single junction photovoltaic cell 552 in cell group 3 568 is connected in series to single junction photovoltaic cell 552 in cell group 4 570 by wire 558. The same logic applies to single junction photovoltaic cells 554 and 556 that are connected to like cells in the adjacent cell groups by wiring connectors 560 and 562 respectively. A single junction photovoltaic cell is only connected in series to the same type photovoltaic cells in adjacent cell groups. This isolation enables the single junction photovoltaic cells to each work at maximum efficiency. In one embodiment the positive output are all at one end (i.e., right end) and all negative output are at the other end (i.e., left end). The use of four cell groups in this example is not limiting. A smaller'or greater number of cell groups is foreseen as is a smaller or greater number of different photovoltaic materials in the single junction photovoltaic cells.

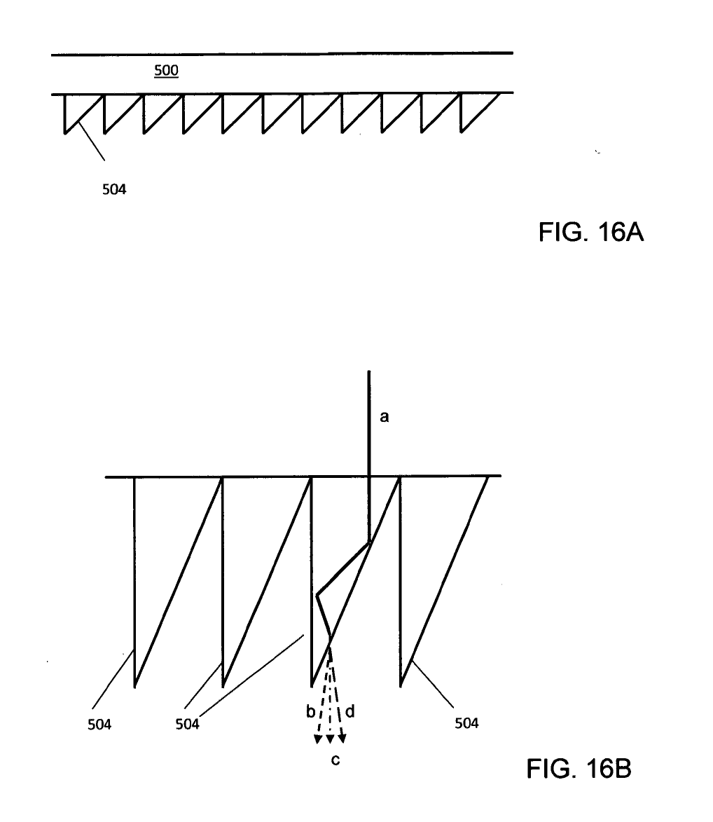

FIG. 16A presents one approach to the separation of colors after the present invention. A substrate 500 has disposed on it a prismatic structure 504 comprising a series of prisms. In one embodiment substrate 500 is cover glass 291 of FIG. 7B.

FIG. 16B presents a detailed view of the action of prism 504. A solar ray a enters the base of prism 504 and is reflected by total internal reflection (TIR) within prism 504. Upon exiting prism 504 on its angled surface solar ray a is divided into rays b, c, and d wherein each ray represents a part of the spectrum of solar ray a and where the rays diverge according the standard principles of optics. The divergence of rays at a common point enables the development of a solar concentrator with different focal points for different wavelength that retains a common focal point for all wavelengths.

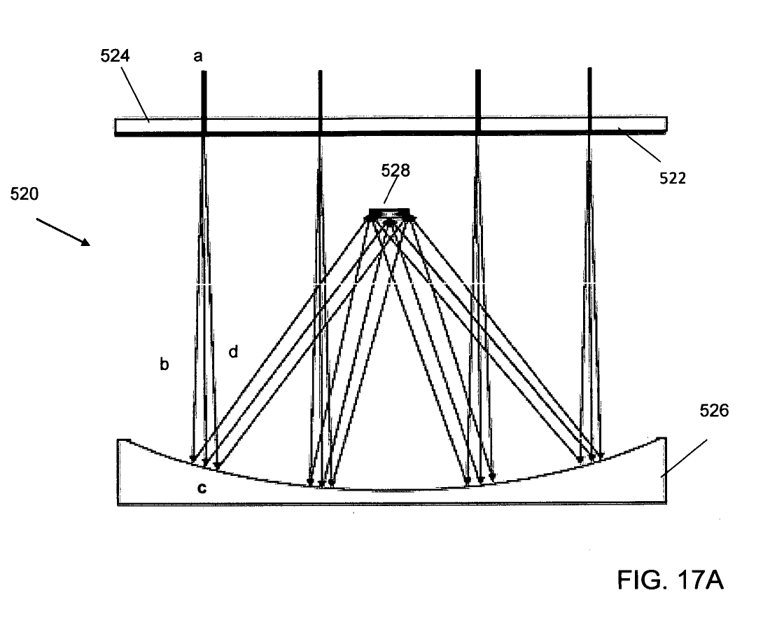

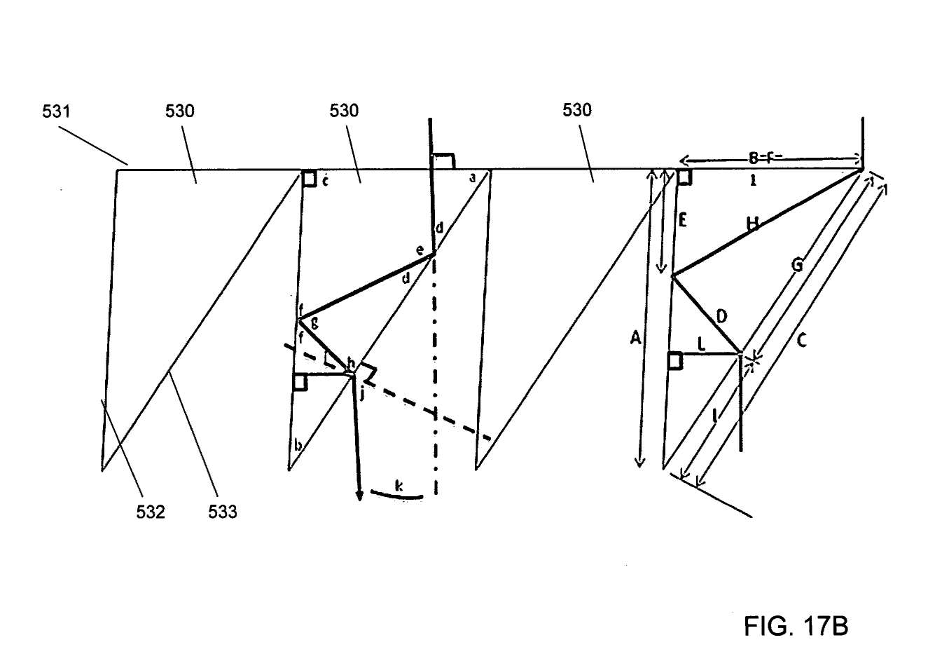

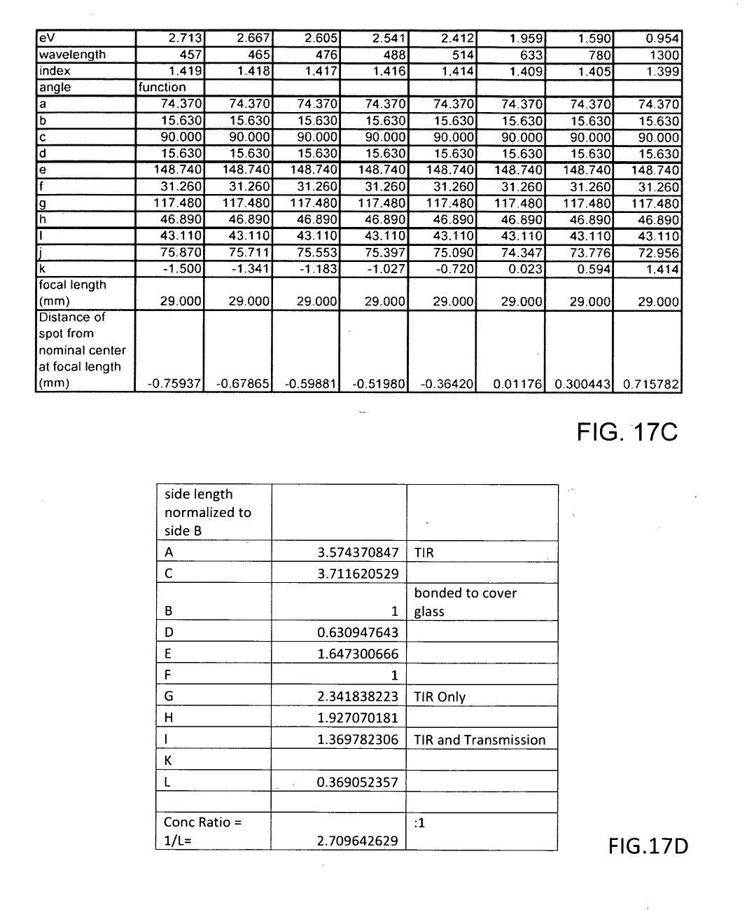

FIG. 17A depicts solar concentrator 520 after the present invention. Prism structure 522 is disposed on the lower surface of substrate 524. Solar ray a passes through substrate 524 and is spread into ‘a continuum of wavelengths each diverging at a different angle from prism structure 522, but substantially centered about an angle parallel to incoming ray a. Three rays are depicted exiting the prism as examples of the behavior of one each of a short, medium and long wave component of the spectrum Single junction photovoltaic structure 528 comprises a plurality of single junction photovoltaic cells after the structure presented in FIG. 15A. Ray b diverges to the left and is reflected by the surface of mirror 526 at an angle equal to the angle of incidence to the tangent of the curves surface at the point of incidence. This results in a shift of the point of incidence on single junction photovoltaic structure 528 to the left side of the landing point for ray c. Ray c is not shifted by prism structure 522 and is incident on single junction photovoltaic structure 528 at the center. Likewise ray d is shifted to the right and is reflected by the surface of mirror 526 to a point to the right of the landing point of ray b on the other side of the landing point for ray c. In one embodiment substrate 524 is the cover glass for solar concentrator 520.

Those of skill in the art will recognize that the actual spread of solar ray a in the prism will depend specifically on the spectrum of solar ray a and will likely represent a continuum of diverging rays of varying wavelength. The purpose of the use of three rays b, c and d is to illustrate the point of divergence and not to claim that there will only be three rays.

FIG. 17B identifies the nomenclature for the sides and solar radiation paths of right triangular prism structure 530 and the angles associated with the path that solar radiation takes in passing through right triangular prism structure 530. Side 533 forms the hypotenuse of prism 530. Side 532 forms the vertical side of prism and side 531 forms the horizontal side of prism 530. Angle e at the intersection of side 531 and 532 is a right angle.

FIG. 17C presents angle data in tabular form for a range of wavelengths entering right triangular prism structure 530. Note that angles a through i for solar radiation passing through right triangular prism structure 530 are equal regardless of wavelength. Angles j and k vary by wavelength as shown in the table with k—the angle relative to the original incident solar radiation—ranging from −1.500° at 457 nanometers (nm) wavelength to +1.414° at 1300 nm wavelength. This effect occurs because of a corresponding shift with wavelength of the index of refraction as shown in the table. With a focal length of mirror 526 of FIG. 17A of 29 millimeters (mm) this is equivalent to a shift in the location of the effective focal position of −0.75937 mm at 457 nm wavelength to an effective focal position of +0.715782 mm at 1300 nm wavelength, a spread of approximately 1.46 mm. The spread can be increased by increasing the focal length or by modifying the prescription of right triangular prism structure 530.

FIG. 17D presents the prescription for the length of the sides and paths of FIG. 17B. All data are normalized to B which is the length of side 531. It is important to note that other prescriptions for right triangular prism structure 530 are possible within the scope of this invention.

While the above is a complete description of the preferred embodiment of the present invention, it is possible to use various alternatives, modifications and equivalents. Therefore, the scope of the present invention should not be determined with reference to the above description but should, instead, be determined with reference to the appended claims, along with their full scope of equivalents. Any feature described herein, whether preferred or not, may be combined with any other features described herein, whether preferred or not. Thus, the invention is not intended to be limited to the embodiment shown herein but is to be accorded the widest scope consistent with the principal and novel features disclosed herein.

I claim:

1. A solar concentrator assembly comprising a plurality of reflector mirrors with gain in two axes arrayed in at least one line,
a plurality of photovoltaic cells affixed to a circuit board,
a heat sink disposed so as to collect and dissipate excess heat generated by the plurality of photovoltaic cells arrayed on a circuit board,
support means suitable for supporting and aligning the plurality of photovoltaic cells affixed to a circuit board attached to a heat sink assembly such that at least one photovoltaic cell is proximate to the focal point of each reflector mirror, and
means for collecting the electric energy generated by said set of photovoltaic cells.

2. The solar concentrator assembly of claim 1 wherein the at least one line of reflector mirrors forms a major structural element of the assembly, and
the at least one line of reflector mirrors comprising a plurality of mirrors and support elements for said plurality of photovoltaic cells affixed electrically and mechanically to a circuit board.

3. The solar concentrator assembly of claim 1 wherein the heat sink assembly forms a major structural element of the assembly,
said heat sink assembly comprising a base plate, a plurality of heat sink fins arrayed along the longitudinal axis of the heat sink, and
a plurality of risers arrayed along the longitudinal axis of the heat sink assembly, being positioned at substantially the center along the transverse axis of the heat sink assembly, and
having suitably placed and sized apertures between said plurality of risers, said plurality of risers having a photovoltaic assembly attached thereto with photovoltaic cells of the photovoltaic assembly substantially centered over the clear aperture.

4. The heat sink assembly of claim 3 wherein the heat sink assembly is formed by extrusion as a single piece.

5. The heat sink assembly of claim 3 wherein the clear apertures on the risers of the heat sink assembly are formed by tool punch.

6. The solar concentrator assembly of claim 1 wherein said reflector mirrors are rotationally symmetric in curvature.

7. A solar concentrator assembly comprising a plurality of reflector mirrors with gain in two axes arrayed in a grid,
a plurality of photovoltaic cells affixed electrically and mechanically to a circuit board,
a heat sink disposed so as to collect heat from the photovoltaic cells and circuit board above the mirror assembly, and transport and translate the heat from the sun facing side of the mirror assembly through said mirror assembly to the underside of the mirror assembly, and
wherein said heat is transfer through a heat spreader to dissipation fins, and thereby dissipate excess heat generated by a plurality of photovoltaic cells affixed to a circuit board, and
support means suitable for supporting and aligning the plurality of photovoltaic cells arrayed on a circuit board attached to a heat sink assembly, and with at least one photovoltaic cell located proximate to the focal point of each reflector mirror, and
means for collecting the electric energy generated by said plurality of photovoltaic cells.

8. The solar concentrator assembly of claim 7 wherein the heat sink assembly forms a major structural element of the assembly, said heat sink assembly comprising a base plate, a plurality of heat sink fins arrayed along the longitudinal axis of the heat sink, and a plurality of risers arrayed along the longitudinal axis of the heat sink assembly, said plurality of risers being positioned at substantially the center of the transverse axis of the heat sink assembly, and
having suitably placed and sized clear apertures, said plurality of risers having a photovoltaic assembly attached thereto with photovoltaic cells of the photovoltaic assembly substantially centered over the aperture.

9. The heat sink assembly of claim 7 wherein the heat sink assembly is formed by extrusion as a single piece.

10. The heat sink assembly of claim 7 wherein the clear apertures on the risers of the heat sink assembly are formed by tool punch.

11. The solar concentrator assembly of claim 7 wherein the reflector mirror are rotationally symmetric in curvature.

12. A solar concentrator assembly comprising a plurality of reflector mirrors with gain in two axes arrayed in at least one line, and
a plurality of photovoltaic cells affixed to a circuit board, wherein at least two single junction photovoltaic cells of different materials are located proximate to the focal point of each reflector mirror, and
a heat sink disposed so as to collect and dissipate excess heat generated by the plurality of photovoltaic cells arrayed on a circuit board; and
support means suitable for supporting and aligning the photovoltaic cells arrayed on a circuit board attached to a heat sink assembly, wherein at least two single junction photovoltaic cells fabricated of different material are placed proximate to the focal point of each reflector mirror, and
means for collecting the electric energy generated by said plurality of photovoltaic cells with electrical energy from one of at least the two single junction photovoltaic cells being collected separately from the electrical energy from another of the at least two single junction photovoltaic cells, and
having a prism assembly comprising a plurality of prism elements affixed to a substrate disposed between the reflective mirror assembly and the sun, with the plane of the substrate substantially perpendicular to the solar axis, such that solar radiation enters the prism assembly and exits with angular separation between differing wavelengths of solar radiation, said prism elements aligned parallel to the transverse axis of said mirror assembly, and
wherein said at least two single junction photovoltaic cells are positioned so as to receive angularly separated solar radiation of a proper wavelength for its material.

13. The solar concentrator assembly of claim 12 wherein the heat sink assembly forms a major structural element of the assembly, said heat sink assembly comprising a base plate, a plurality of heat sink fins arrayed along the longitudinal axis of the heat sink, and a plurality of risers arrayed along the longitudinal axis of the heat sink assembly, said plurality of risers being positioned at substantially the center of the transverse axis of the heat sink assembly, and
having suitably placed and sized clear apertures, said plurality of risers having a photovoltaic assembly attached thereto with photovoltaic cells of the photovoltaic assembly substantially centered over the aperture, and positioned so as to receive solar radiation of the proper wavelength for its material.

14. The solar concentrator assembly of claim 12 wherein the mirror assembly comprises two half mirror segments joined together to form a full mirror segment.

15. The solar concentrator of claim 12 wherein the substrate to which the prism assembly is affixed is a weather cover glass for a panel assembly comprising a plurality of solar concentrator assemblies.

16. The heat sink assembly of claim 12 wherein the heat sink assembly is formed by extrusion as a single piece.

17. The heat sink assembly of claim 12 wherein the clear apertures on the risers of the heat sink assembly are formed by tool punch.

18. The solar concentrator assembly of claim 12 where at least one single junction photovoltaic cells is a quantum well single junction photovoltaic cell.
